(19) United States
(12) Patent Application Publication
(10) Pub. No.: US 2025/0311189 A1
(43) Pub. Date: Oct. 2, 2025

(54) INDEPENDENTLY CONTROLLED MEMORY CELLS AROUND STACKED SEMICONDUCTOR REGIONS

(71) Applicant: Intel Corporation, Santa Clara, CA (US)

(72) Inventor: Abhishek A. Sharma, Portland, OR (US)

(73) Assignee: Intel Corporation, Santa Clara, CA (US)

(21) Appl. No.: 18/619,774

(22) Filed: Mar. 28, 2024

(51) Int. Cl. H10B 12/00; H01L 23/522; H01L 23/528; H01L 29/06; H01L 29/417; H01L 29/778; H01L 29/786; H10B 80/00

(52) U.S. Cl. CPC H10B 12/31; H01L 23/5226; H01L 23/5283; H10B 12/03; H10B 12/485; H10B 80/00; H10D 30/47; H10D 30/6729; H10D 30/6757; H10D 62/118; H01L 2225/06541

(57) ABSTRACT

Described herein are vertically stacked memory cells that include one transistor and one capacitor. Each memory cell in the stack is formed around a single semiconductor structure in stack of semiconductor structures, such as nanoribbons. A first end of the semiconductor structures is coupled to a bit line, and a capacitor is formed around a second end of each of the semiconductor structures. A gate may be formed around a central portion of each of the semiconductor structures. In some cases, two independent gates, one over the semiconductor structure and one under the semiconductor structure, may be electrically independent and separately controlled.

### BACKGROUND

Embedded memory is important to the performance of modern system-on-a-chip (SoC) technology. Typically, memory assemblies (e.g., static random-access memory (SRAM) and dynamic random-access memory (DRAM)) include transistors arranged in a single layer. Low power and high-density embedded memory is used in many different computer products and further improvements are always desirable.

A DRAM memory cell typically includes a capacitor for storing a bit value or a memory state (e.g., logical “1” or “0”) of the cell and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one source/drain (S/D) region/terminal of the access transistor (e.g., to the source region of the access transistor), while the other S/D region of the access transistor may be coupled to a bitline (BL), and a gate terminal of the transistor may be coupled to a wordline (WL). Since such a memory cell can be fabricated with as little as a single access transistor, it can provide higher density and lower standby power versus some other types of memory in the same process technology, e.g., SRAM.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-section across a nanoribbon-based transistor showing the source, gate, and drain.

FIG. 1B is a cross-section of the nanoribbon-based transistor through the plane AA′ in FIG. 1A.

FIG. 2 is an electrical circuit diagram of an example one 1T-1C memory cell, according to some embodiments of the present disclosure.

FIG. 3A is a cross-section illustrating a stack of 1T-1C memory cells formed around nanoribbons, according to some embodiments of the present disclosure.

FIG. 3B is a gate cross-section through the plane CC′ in FIG. 3A, according to some embodiments of the present disclosure.

FIG. 3C is a capacitor cross-section through the plane DD′ in FIG. 3A, according to some embodiments of the present disclosure.

FIG. 4A is a cross-section illustrating a stack of 1T-1C memory cells formed around nanoribbons with via connections to different capacitors, according to some embodiments of the present disclosure.

FIG. 4B is a cross-section illustrating multiple stacks of 1T-1C memory cells with via connections to different gate lines, according to some embodiments of the present disclosure.

FIG. 5A is cross-section illustrating a stack of 1T-1C memory cells formed around nanoribbons with independent top and bottom gates, according to some embodiments of the present disclosure.

FIG. 5B is a gate cross-section through the plane GG′ in FIG. 5A, according to some embodiments of the present disclosure.

FIG. 6 is a flow diagram of a process for fabricating a stack of nanoribbons with independent top and bottom gates, according to some embodiments of the present disclosure.

FIGS. 7A and 7B are two perpendicular cross-sections illustrating layers of a channel material and two sacrificial materials, according to some embodiments of the present disclosure.

FIGS. 8A and 8B are two perpendicular cross-sections illustrating individuated stacks of the layered channel material and sacrificial materials, according to some embodiments of the present disclosure.

FIGS. 9A and 9B are two perpendicular cross-sections illustrating formation of anchors around the stacks of the layered channel material and sacrificial materials, according to some embodiments of the present disclosure.

FIGS. 10A and 10B are two perpendicular cross-sections illustrating removal of a first sacrificial material from the stacks, according to some embodiments of the present disclosure.

FIGS. 11A and 11B are two perpendicular cross-sections illustrating a first gate stack deposited on the channels, according to some embodiments of the present disclosure.

FIGS. 12A and 12B are two perpendicular cross-sections illustrating removal of a second sacrificial material from the stacks, according to some embodiments of the present disclosure.

FIGS. 13A and 13B are two perpendicular cross-sections illustrating a second gate stack deposited on the channels, according to some embodiments of the present disclosure.

FIGS. 14A and 14B illustrate two steps in forming a staircase structure for the gate vias, according to some embodiments of the present disclosure.

FIG. 15 is a cross-section of an alternate embodiment of stacked 1T-1C memory cells formed around nanoribbons, in accordance with any of the embodiments disclosed herein.

FIG. 16 is a top view of a wafer and dies that include one or more stacks of 1T-1C memory cells formed around nanoribbons in accordance with any of the embodiments disclosed herein.

FIG. 17 is a cross-sectional side view of an IC device that may include one or more stacks of 1T-1C memory cells formed around nanoribbons in accordance with any of the embodiments disclosed herein.

FIG. 18 is a cross-sectional side view of an IC device assembly that may include one or more stacks of 1T-1C memory cells formed around nanoribbons in accordance with any of the embodiments disclosed herein.

FIG. 19 is a block diagram of an example computing device that may include one or more stacks of 1T-1C memory cells formed around nanoribbons in accordance with any of the embodiments disclosed herein.

FIG. 20 is a block diagram of an example processing device that includes an IC device with one or more stacks of 1T-1C memory cells formed around nanoribbons in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating IC devices implementing DRAM memory cells around stacked nanosheets as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

One challenge with DRAM cells is that, given a usable surface area of a substrate, there are only so many transistors that can be formed in that area, placing a significant limitation on the density of memory cells incorporating such transistors. In conventional solutions, attempts to increase memory density have included decreasing the critical dimensions of the memory cells, which requires ever-increasing process complexity and cost, resulting in diminishing returns and expected slow pace of memory scaling for future nodes.

Embodiments of the present disclosure may enable increased memory density using a vertically stacked memory design, where a stack of nanosheets is used to provide a stack of individually-controlled DRAM memory cells. In particular, each nanosheet in the stack can be used to form an independent transistor, and a capacitor can be coupled to each nanosheet in the stack.

Transistors, including access transistors for memory cells, typically include a gate stack coupled to a semiconductor channel, such as a nanoribbon or a stack of nanoribbons. A gate stack often includes a gate electrode and a gate dielectric, with the gate dielectric formed between the gate electrode and the channel material. In a nanoribbon transistor, the gate dielectric is formed around each nanoribbon, and the gate electrode is formed over and around the gate dielectric, including in spaces between adjacent nanoribbons in the stack. In some implementations of nanoribbon transistors, the gate material surrounds a stack of multiple nanoribbons, so that the stack of nanoribbons act as a single channel region in a single transistor. A source region is formed at one end of the nanoribbons, and a drain region is formed at the opposite end of the nanoribbons, thus realizing a three-terminal device.

Nanoribbons are often small structures, with a low amount of current passing through each individual nanoribbon. In many nanoribbon-based transistors, multiple nanoribbons are used together in a single transistor to provide adequate current flow through the transistor. In general, when transistors operate at lower temperatures, they have improved performance. For example, electron mobility in semiconductors improves at lower temperatures, which can lead to increased drive currents across semiconductor regions, e.g., across transistors or individual nanoribbons. In addition, transistors at lower temperatures generally experience lower leakage than transistors operating at higher temperatures. These factors can allow smaller transistors when the IC device is operating at a lower temperature.

In some cases, e.g., in low-temperature applications where the drive current through an individual nanoribbon is greater, transistors can be built around individual nanoribbons in a stack, rather than around full stacks of nanoribbons. For a memory application, each nanoribbon in the stack can serve as the basis for an access transistor. Capacitors may be similarly vertically stacked, e.g., a capacitor can be coupled to the end of each nanoribbon, thus realizing a vertical stack of 1T-1C memory cells.

Memory devices, and assemblies including such memory devices (e.g., IC devices, electronics packages, etc.), that include a nanoribbon-based access transistor coupled to a capacitor are described herein. A stack of nanoribbons may be used to form a stack of memory devices. A transistor is formed around each nanoribbon, and a capacitor is formed at the end of each nanoribbon. Thus, multiple 1T-1C memory cells may be stacked vertically, with a nanoribbon forming the base structure of each 1T-1C memory cell.

A gate line may be formed across multiple memory cells in different stacks. For example, if multiple stacks of memory cells are arranged side-by-side, a first gate line spans the top nanoribbon of each stack, a second gate line spans the next nanoribbon down in each stack, etc. Connections from the different gate lines to a metallization layer may be formed in a staircase fashion, as illustrated in the figures. The gate lines may act as the word line to the access transistors. A single source or drain (S/D) region may be coupled to all of the nanoribbons in a given stack and act as a bit line to the access transistors. The end of the nanoribbon on the opposite side of the gate from the S/D region is coupled to one capacitor plate. For example, a first conductive layer (forming a first capacitor plate) may be formed over or around the end of the nanoribbon opposite the S/D region, a dielectric layer formed over or around the first conductive layer, and a second conductive layer (forming a second capacitor plate) formed over or around the dielectric layer. The second conductive layers of a stack of transistors may be arranged in a staircase fashion, with connections to the metallization layer forming different plate lines to each capacitor.

In some embodiments, a gate may wrap around a nanoribbon channel. In other embodiments, a nanoribbon may be coupled to two gates, one over top of the nanoribbon and one below the nanoribbon. These gates may be coupled to two different gate lines that are independently controlled. Each gate line may be used to control current flow through the transistor and access to the capacitor. The gate lines may be formed from different conductive materials, e.g., metals with different work functions. For example, a first gate line that applies a lower voltage may be used when the IC device is relatively new, and a second gate line that applies a higher voltage may be used after the IC device has been in use for a period of time.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

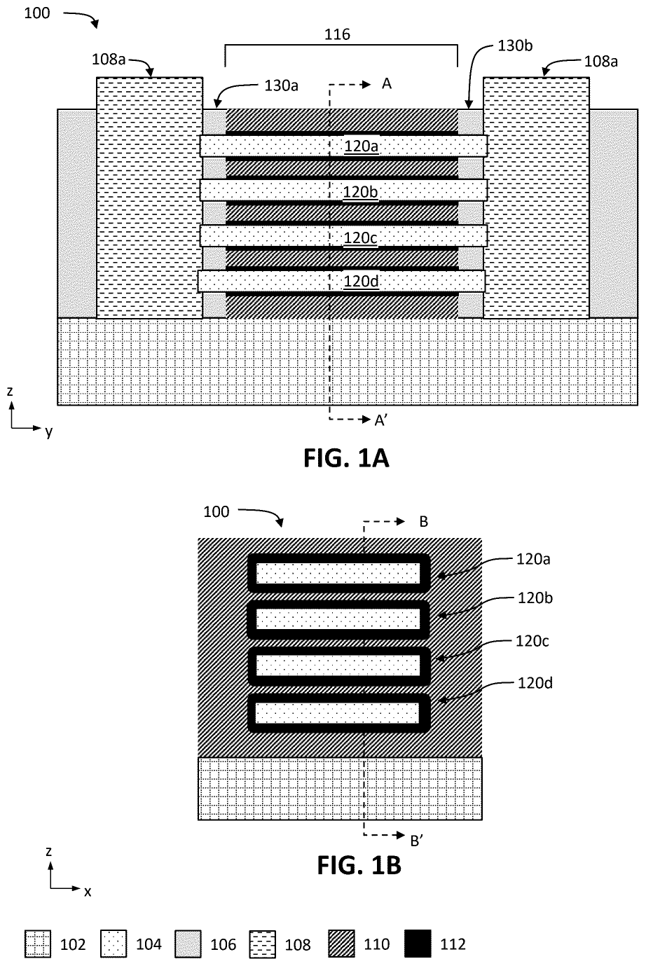

For convenience, if a collection of drawings designated with different letters are present, e.g., FIGS. 1A-1B, such a collection may be referred to herein without the letters, e.g., as “FIG. 1.”

### Example Nanoribbon Transistor

FIGS. 1A-1B illustrate an example architecture of a nanoribbon-based transistor. FIG. 1A is a cross-section across a transistor 100 showing the source, gate, and drain. FIG. 1B is a cross-section across the gate regions of the transistor 100. FIG. 1B is a cross-section through the plane AA′ in FIG. 1A, and FIG. 1A is a cross-section through the plane BB′ in FIG. 1B. The nanoribbon-based transistor 100 illustrates certain structures and materials that may be used in the vertically stacked memory cells formed around nanoribbons discussed further below.

A number of elements referred to in the description of FIGS. 1A, 1B, 3-5, and 7-14, and with reference numerals are illustrated in these figures with different patterns, with a legend at the bottom of the page showing the correspondence between the reference numerals and patterns. The legend illustrates that FIGS. 1A and 1B use different patterns to show a support structure 102, a channel material 104, a dielectric material 106, a source or drain (S/D) region 108, a gate electrode 110, and a gate dielectric 112.

In the drawings, some example structures of various devices and assemblies described herein are shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

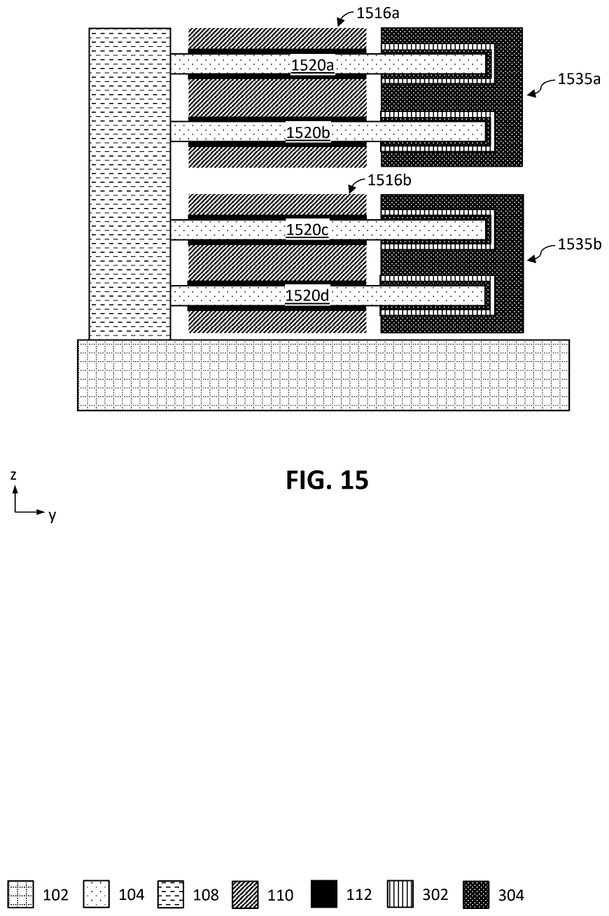

In general, implementations of the present disclosure may be formed or carried out on a support structure, e.g., the support structure 102 illustrated in FIG. 1. The support structure 102 may be, e.g., a substrate, a die, a wafer or a chip. For example, the support structure may be the wafer 1500 of FIG. 15A, discussed below, and may be, or be included in, a die, e.g., the singulated die 1502 of FIG. 15B, discussed below. The support structure 102 extends along the x-y plane in the coordinate system shown in FIG. 1. In some embodiments, a support structure 102 may be used during a fabrication process and later removed. For example, a top side of the transistor 100 may be attached to a second support structure (e.g., a second one of the support structures 102, which may be referred to as a carrier structure), and the support structure 102 over which the transistor 100 is formed may be removed to expose the back side of the transistor 100.

In some embodiments, a support structure may be a substrate that includes silicon and/or hafnium. More generally, the support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group Ill-V materials (i.e., materials from groups Ill and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the substrate may be formed are described here, any material that may serve as a foundation upon which a semiconductor device including one or more nanoribbon transistors, as described herein, may be built falls within the spirit and scope of the present disclosure.

In FIGS. 1A and 1B, a transistor 100 is formed over a support structure 102. The transistor 100 includes a channel material 104 formed into four nanoribbons stacked on top of each other. In other examples, the transistor 100 may include more or fewer nanoribbons, e.g., one, two, three, five, six or more nanoribbons. The channel material 104 may be a semiconductor, such as silicon or other semiconductor materials described herein.

The transistor 100 includes nanoribbons 120a, 120b, 120c, and 120d, referred to collectively as nanoribbons 120 or individually as a nanoribbon 120. Each nanoribbon 120 is at a different height in the z-direction in the orientation shown in FIGS. 1A and 1B, i.e., a different distance from the support structure 102, where the nanoribbon 120a is the greatest distance from the support structure 102, and the nanoribbon 120d is the smallest distance from the support structure 102. S/D regions 108a and 108b are formed at either end of the nanoribbon channels 120, as illustrated in FIG. 1A.

In general, to form nanoribbon channels such as the nanoribbon channels 120, alternating layers of the channel material 104 and a sacrificial material are deposited over the support structure 102. The sacrificial material is removed from the stack and replaced with other material, e.g., material for forming a gate stack 116, so the sacrificial material is not shown in FIG. 1. The channel material 104 and sacrificial materials include different materials. In one example, the channel material 104 is silicon, while the sacrificial material includes silicon and germanium. The sacrificial material may be chosen to have a similar crystal structure to the channel material 104, so that monocrystalline layers of the channel material 104 (or substantially monocrystalline layers, e.g., with a grain size of at least 5 nanometers, at least 20 nanometers, at least 50 nanometers, or at least 100 nanometers) and monocrystalline layers of the sacrificial material (or substantially monocrystalline layers) may be formed over each other. In different embodiments, the channel material 104 and/or the sacrificial material may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide 11 compound, where arsenic Ill is in combination with another element such as boron, aluminum, gallium, or indium), or any group Ill-V material (i.e., materials from groups Ill and V of the periodic system of elements).

More generally, the channel material 104 may be composed of semiconductor material systems including, for example, N-type or P-type materials systems. The channel material 104 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. The channel material 104 may include one or more of cobalt oxide, copper oxide, ruthenium oxide, nickel oxide, niobium oxide, copper peroxide, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc.

In some cases, multiple channel materials may be included within an IC device. For example, an IC device may include both N-type metal-oxide-semiconductor (NMOS) transistors and P-type MOS (PMOS) transistors, e.g., alternating rows of NMOS and PMOS transistors. NMOS and PMOS logic can use different groups of channel material 104, e.g., silicon may be used to form an N-type semiconductor channel, while silicon germanium may be used to form a P-type semiconductor channel. In some cases, a single channel material 104 is used (e.g., silicon), and different portions (e.g., channel material to form different transistors) may include different dopants, e.g., N-type dopants for NMOS transistors and P-type dopants for PMOS transistors.

The S/D regions 108 may be formed from one or more layers of doped semiconductors, metals, metal alloys, or other materials. For example, the S/D regions 108 may include a doped semiconductor, such as silicon or another semiconductor doped with an N-type dopant or a P-type dopant. The S/D regions 108 may include multiple layers with different levels of conductivity, e.g., a doped semiconductor followed by a more highly doped semiconductor, or a semiconductor followed by metal.

A central portion of each of the nanoribbon channels 120 is surrounded by a gate stack 116, which in this example, includes a gate electrode 110 and gate dielectric 112. Nanoribbon transistors often include a gate dielectric that surrounds the nanoribbon channels 120, and a gate electrode that surrounds the gate dielectric. While not specifically shown, in some cases, the gate dielectric 112 around each nanoribbon channel 120 includes multiple layers, e.g., an oxide layer and a high-k dielectric layer. The oxide layer may be grown directly on the nanoribbon channels 120, and the high-k dielectric may surround the oxide. The oxide may include oxygen in combination with the channel material 104. For example, if the nanoribbon channels are formed from silicon, the gate dielectric 112 may include a layer of silicon oxide. The high-k dielectric may be formed over the oxide. The gate electrode 110 surrounds the gate dielectric 112, e.g., the high-k dielectric (if included). In this example, the gate electrode 110 is above and below the nanoribbon stack, and between adjacent nanoribbons 120.

The gate electrode 110 includes a conductive material, such as a metal. The gate electrode 110 may include at least one P-type work function metal or N-type work function metal, depending on whether the transistor 100 is a PMOS transistor or an NMOS transistor. For a PMOS transistor, metals that may be used for the gate electrode 110 may include, but are not limited to, ruthenium, palladium, platinum, cobalt, nickel, and conductive metal oxides (e.g., ruthenium oxide). For an NMOS transistor, metals that may be used for the gate electrode 110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). The gate electrode 110 may include a stack of two or more metal layers, where one or more metal layers are work function metal layers and at least one metal layer is a fill metal layer.

The gate dielectric 112 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. The gate dielectric 112 may have a thickness between about 0.5 nanometers and 3 nanometers, including all values and ranges therein, e.g., between about 1 and 3 nanometers, or between about 1 and 2 nanometers.

Regions of the transistor 100 outside of the nanoribbons 120, gate stack 116, and S/D regions 108 are filled in with a dielectric material 106. In the region between the gate stack 116 and the S/D regions 108, the dielectric material 106 forms a series of cavity spacers. Cavity spacers, also referred to as “dimple spacers” or “inner spacers,” provide electrical isolation between the S/D regions 108 formed at the ends of the nanoribbons and the gate electrode 110 deposited around the nanoribbons 120.

FIG. 1 illustrates a single nanoribbon transistor 100. In IC devices, many similar or identical transistors are arranged within a transistor layer. The dielectric material 106 and/or different dielectric materials may provide isolation between different transistors, or between other conductive materials in or near the transistor layer.

### Example 1T-1C Memory Cell

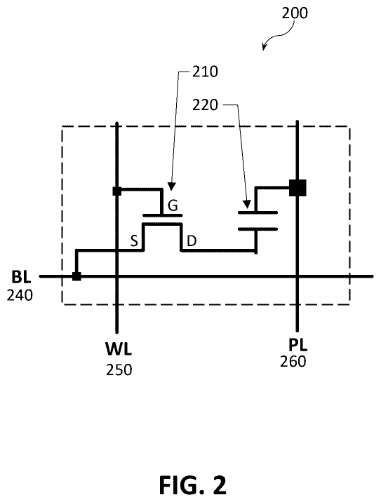

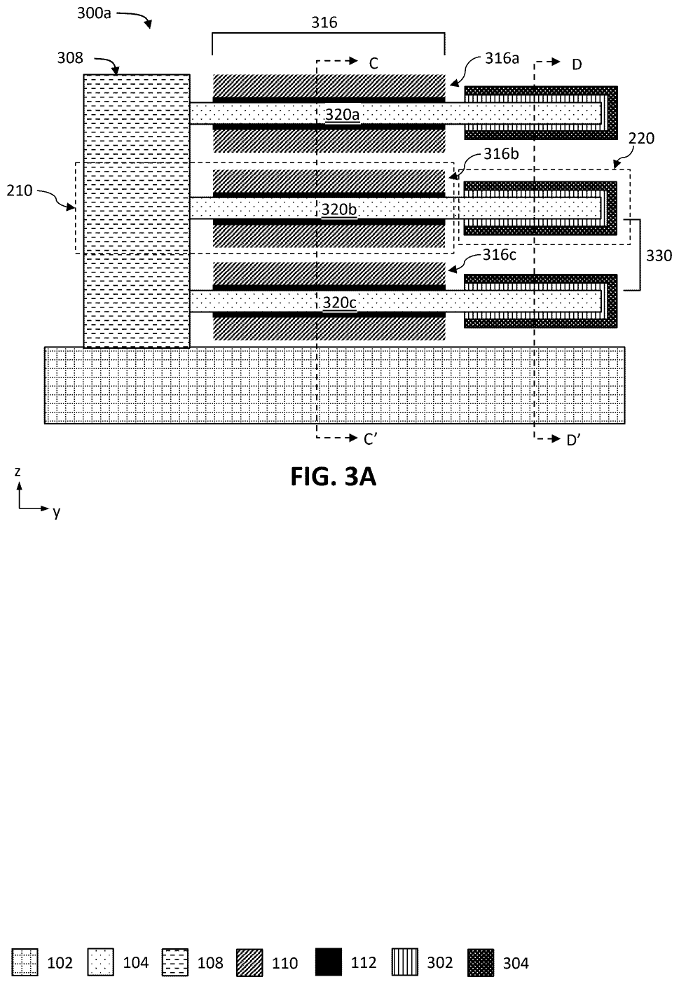

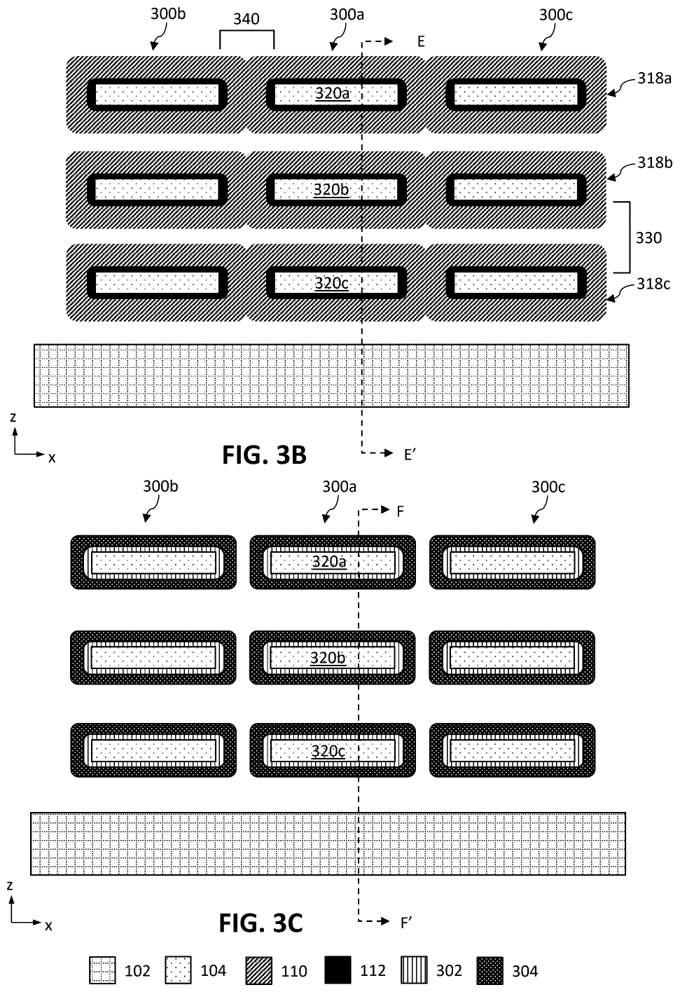

FIG. 2 is an electrical circuit diagram of an example one access transistor (1T) and one capacitor (1C) (1T-1C) memory cell 200, according to some embodiments of the present disclosure. The 1T-1C cell 200 is an example DRAM memory cell that may be formed along a nanoribbon. For example, FIG. 3A, discussed below, shows a stack of three memory cells; each of the three memory cells in FIG. 3 is represented by the memory cell 200.

As shown, the 1T-1C cell 200 may include an access transistor 210 and a capacitor 220. The access transistor 210 has a gate terminal, a source terminal, and a drain terminal, indicated in the example of FIG. 2 as terminals G, S, and D, respectively. In the following, the terms “terminal” and “electrode” may be used interchangeably. Furthermore, for S/D terminals, the terms “terminal” and “region” may be used interchangeably.

As shown in FIG. 2, in the 1T-1C cell 200, the gate terminal of the access transistor 210 is coupled to a WL 250, one of the S/D terminals of the access transistor 210 (in this example, the source terminal, S) is coupled to a BL 240, and the other one of the S/D terminals of the access transistor 210 (in this example, the drain terminal, D) is coupled to a first electrode of the capacitor 220. As also shown in FIG. 2, the other electrode of the capacitor 220 is coupled to a capacitor plateline (PL) 260. As is known in the art, WL, BL, and PL may be used together to read and program the capacitor 220.

Each of the BL 240, the WL 250, and the PL 260, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

### Example Stacks of 1T-1C Memory Cells Around Nanoribbons

FIG. 3A is a cross-section illustrating a stack 300a of 1T-1C memory cells formed around nanoribbons, according to some embodiments of the present disclosure. FIG. 3B is a gate cross-section through the plane CC′ in FIG. 3A, and FIG. 3C is a capacitor cross-section through the plane DD′ in FIG. 3A. FIG. 3A illustrates the planes EE′ in FIG. 3B and FF′ in FIG. 3C.

Turning first to FIG. 3A, a stack of three nanoribbons 320a, 320b, and 320c are over a support structure 102, which may be the support structure 102 described with respect to FIG. 1. An access transistor and a capacitor of a memory cell are formed around each of the nanoribbons 320. For example, an access transistor 210 is formed around a left side of the nanoribbon 320b, and a capacitor 220 is formed around a right side of the nanoribbon 320b. Similarly, an access transistor 210 is formed around the left side of the nanoribbons 320a and 320c, while a capacitor 220 is formed around the right side of the nanoribbons 320a and 320c.

The nanoribbons 320 include the channel material 104, which may be the channel material 104 described with respect to FIG. 1. The nanoribbons 320a, 320b, and 320c are referred to collectively as nanoribbons 320 or individually as a nanoribbon 320. The nanoribbons 320 may be any three-dimensional semiconductor structures around which the memory cells described herein may be formed, including, for example, nanowires with a square or circular cross-section, or nanosheets with a wider rectangular cross section. The term nanosheet is sometimes used to highlight the relative breadth and thinness of a particular nanoribbon structure. For example, the term nanosheet may indicate that a structure has a small height (in the z-direction in the example coordinate system) and a broader width (into the page in FIG. 3A, i.e., in the x-direction in the coordinate system shown) compared to other nanostructures, like nanowires. In other embodiments, the nanoribbons 320 may have cross-sections that are squares with rounded corners, rectangles with rounded corners, ovals, or other shapes.

The nanoribbons 320 each have an elongated structure that extends over the support structure 102. Each nanoribbon 320 extends primarily in the y-direction in the coordinate system used in FIGS. 3A and 3B, and thus the nanoribbon structures are considered to be elongated in this direction. The direction in which the nanoribbons 320 extend is parallel to the support structure 102; this direction in which the nanoribbons 320 extend is also parallel to the other nanoribbons in the stack.

Each nanoribbon 320 is at a different height in the z-direction in the orientation shown in FIGS. 3A and 3B, i.e., a different distance from the support structure 102, where the nanoribbon 320a is the greatest distance from the support structure 102, and the nanoribbon 320c is the smallest distance from the support structure 102. While three nanoribbons 320a-320c are shown, forming a stack 300a of three memory cells, in other embodiments, the stack 300a may include more or fewer nanoribbons, e.g., one, two, four, five, six or more nanoribbons 320, and a corresponding number of memory cells.

An S/D region 308 is at one end of the nanoribbons 320, as illustrated in FIG. 3A. The S/D region 308 may include the S/D materials 108 described with respect to FIG. 1. A central portion of each of the nanoribbons 320 is surrounded by a gate stack 316, which like the gate stack 116, includes a gate electrode 110 and gate dielectric 112. The gate dielectric 112 surrounds the nanoribbons 320, and the gate electrode 110 surrounds the gate dielectric 112. The gate dielectric 112 and gate electrode 110 may include any of the materials described with respect to FIG. 1. As described with respect to FIG. 1, in some cases, the gate dielectric 112 includes multiple layers, e.g., an oxide layer and a high-k dielectric layer. The oxide layer may be grown directly on the nanoribbons 320, and the high-k dielectric may surround the oxide. The oxide may include oxygen in combination with the channel material 104. The gate electrode 110 may also include multiple layers, e.g., layers of different conductive materials.

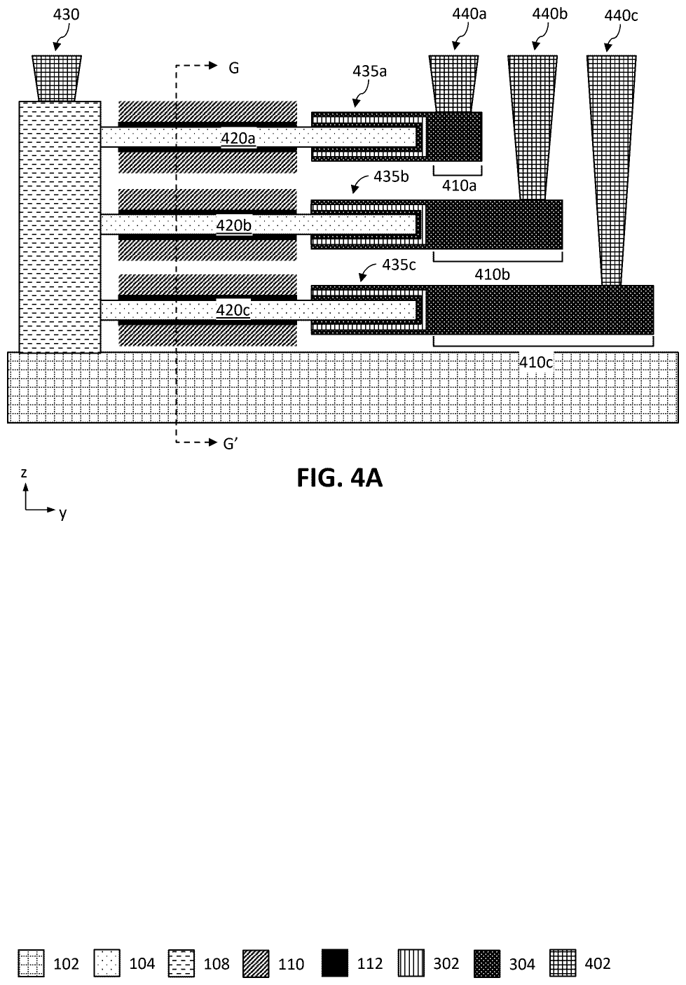

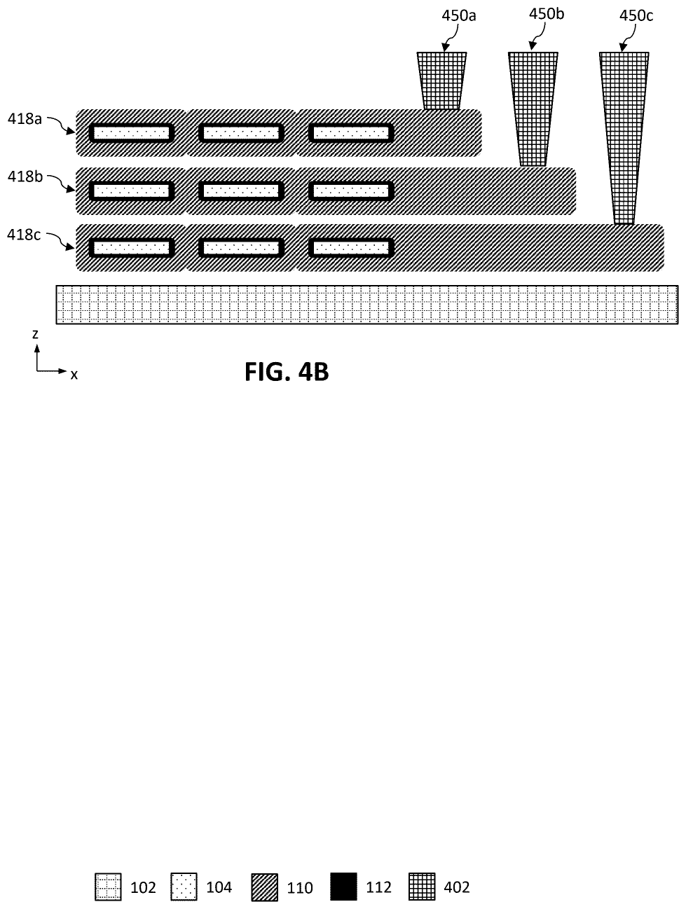

In FIG. 1, the gate electrode 110 spanned areas between adjacent nanoribbons 120, e.g., the gate electrode 110 filled in the area between the nanoribbons 120a and 120b. In contrast, in FIG. 3A, the gate electrodes around different nanoribbons 320 are physically and electrically isolated from each other. Thus, each nanoribbon 320 has its own independent gate stack, i.e., the nanoribbon 320a is surrounded by the gate stack 316a, the nanoribbon 320b is surrounded by the gate stack 316b, and the nanoribbon 320c is surrounded by the gate stack 316c. To obtain independent gate stacks, the distance 330 between adjacent nanoribbons 320 in the stack may be relatively large, e.g., larger than the distance between adjacent nanoribbons 120 in the transistor 100 shown in FIG. 1. The independent gate stacks enables the formation of independent access transistors 210 around each nanoribbon 320. In particular, referring to FIG. 2, the S/D region 308 corresponds to or is coupled to the BL 240, and is coupled to multiple transistors, i.e., the three nanoribbons 320. Each gate stack 316a, 316b, and 316c is coupled to a separate WL 250, as illustrated in FIG. 4B, for example.

To the right of each gate stack 316, the right end of the nanoribbon 320, i.e., the end of the nanoribbon 320 opposite the end coupled to the S/D region 308, is coupled to a capacitor 220. The gate stack 316 is between these two ends of the nanoribbon 320. In this example, the capacitor is a semiconductor-insulator-metal (SIM) capacitor, where the channel material 104 of the nanoribbon 320 forms a first plate (e.g., corresponding to the lower plate of the capacitor 220 of FIG. 2), and a metal material 304 surrounding the end of the nanoribbon 320 forms a second plate (e.g., corresponding to the upper plate of the capacitor 220 of FIG. 2). A dielectric material 302 is between the channel material 104 and the metal material 304, forming an insulator layer of the SIM capacitor. In some embodiments, the ends of the nanoribbon 320 acting as the first plate of the capacitor may be doped to increase their conductivity. In other embodiments, an inner metal layer is between the channel material 104 and the dielectric material 302, realizing a MIM capacitor that surrounds the end of the nanoribbon 320. An example of a MIM capacitor is shown in FIG. 4A.

In the example of FIG. 3, the dielectric material 302 surrounds the nanoribbon 320, and the metal material 304 surrounds the dielectric material 302. The capacitors may be formed by exposing the ends of the nanoribbons 320 and conformally depositing the capacitor materials (e.g., the dielectric material 302 and the metal material 304) around the exposed ends of the nanoribbons 320. In other embodiments, the capacitor layers may not surround the ends of the nanoribbons 320 from all sides, but instead, may be formed over one side (e.g., the top side or the bottom side) or a subset of sides (e.g., the top and bottom sides) of the nanoribbons 320.

The dielectric material 302 forming the insulator layer may be deposited using any suitable technique for conformally depositing materials, such as atomic layer deposition (ALD) or chemical vapor deposition (CVD). Conformal deposition generally refers to deposition of a certain coating on any exposed surface of a given structure. A conformal coating may, therefore, be understood as a coating that is applied to exposed surfaces of a given structure, and not, for example, just to the horizontal surfaces.

The dielectric material 302 may include any suitable material for acting as a capacitor insulator. Examples of such materials include, but are not limited to, dielectric materials known for their applicability in ICs, such as low-k dielectric materials. Examples of dielectric materials that may be used as the dielectric material 302 may include, but are not limited to, silicon dioxide (SiO2), carbon-doped oxide (CDO), silicon nitride, fluorosilicate glass (FSG), silicon nitride, and organosilicates such as silsesquioxane, siloxane, or organosilicate glass. In some embodiments, the dielectric material 302 includes organic polymers such as polyimide, polynorbornenes, benzocyclobutene, perfluorocyclobutane, or polytetrafluoroethylene (PTFE). Still other examples of low-k dielectric materials that may be used as the dielectric material 302 include silicon-based polymeric dielectrics such as hydrogen silsesquioxane (HSQ) and methylsilsesquioxane (MSQ).

The metal material 304 forming the metal layer or metal plate of the capacitor 220 may also be deposited using any suitable technique for conformally depositing materials. The metal material 304 may include one or more of any suitable electrically conductive materials (conductors). Such materials may include any suitable electrically conductive material, alloy, or a stack of multiple electrically conductive materials. In some embodiments, the metal material 304 may include one or more metals or metal alloys, with metals such as copper, ruthenium, palladium, platinum, cobalt, nickel, hafnium, zirconium, titanium, tantalum, and aluminum. In some embodiments, the metal material 304 may include one or more electrically conductive alloys, oxides (e.g., conductive metal oxides), carbides (e.g., hafnium carbide, zirconium carbide, titanium carbide, tantalum carbide, and aluminum carbide, tungsten, tungsten carbide), or nitrides (e.g., hafnium nitride, zirconium nitride, titanium nitride, tantalum nitride, and aluminum nitride) of one or more metals.

FIG. 3B is a gate cross-section through the plane CC′ in FIG. 3A. As noted above, the three gate stacks 316a, 316b, and 316c along a vertical stack 300a of memory cells are not connected and are electrically isolated. In the x-z cross-section illustrated in FIG. 3B, memory cells in different stacks 300b, 300a, and 300c are physically and electrically connected in the horizontal direction by a gate line 318. For example, the gate stack 316a around the upper nanoribbon 320a is electrically and physically coupled to similar gate stacks around the upper nanoribbon in the stack 300b (to the right of the stack 300a) and the upper nanoribbon in the stack 300c (to the left of the stack 300a). These connected gate stacks form a gate line 318a. Similar gate lines 318b and 318c are along the lower nanoribbon channels in the stacks 300. The gate lines 318 extend in a direction perpendicular to the length of the nanoribbons 320. In this example, the nanoribbons 320 and, more generally, the individual memory cells extend from their first end (i.e., the end of the S/D region 308) to their second end (i.e., the capacitor end) along the y-direction, while the gate lines 318 extend in the x-direction.

The spacing of the nanoribbons within each stack 300 and between adjacent stacks 300, along with the selected deposition process parameters, may enable the formation of horizontal gate lines. For example, the horizontal distance 340 between nanoribbons 320 may be less than the vertical distance 330 between nanoribbons 320. The gate electrode 110 and gate dielectric 112 are deposited using a conformal deposition process, such as ALD, as discussed above. The deposition parameters (e.g., bias or voltage) may be selected such that the gate electrode 110 tends to deposit around the lower layers more quickly than around the upper layers, to prevent joined upper gate electrodes (e.g., electrodes along the gate stack 318c) from blocking deposition of the gate electrode 110 around the lower gate electrodes (e.g., electrodes along the gate stacks 318a and 318b).

FIG. 3C is a capacitor cross-section through the plane DD′ in FIG. 3A. FIG. 3C illustrates the layering of the dielectric material 302 and metal material 304 around the channel material 104, forming the capacitors 220. Unlike the gate stacks 316 forming the gate lines 318, as shown in FIG. 3B, the capacitors are not connected together in the horizontal direction, e.g., the metal material 304 does not extend between the vertical stacks 300b, 300a, and 300c. The total thickness of the gate stacks 316 (e.g., the thickness of the gate dielectric 112 and gate electrode 110) may be greater than the total thickness of the insulator and metal capacitor layers (e.g., the thickness of the dielectric material 302 and metal material 304). In some embodiments, the channel material 104 may be thinned at the end used for forming the capacitors, so that the dielectric material 302 and metal material 304 may be deposited around each nanoribbon 320 without touching in the horizontal or vertical directions.

While not specifically, shown, regions of the memory cells outside of the nanoribbons 120, gate stacks 316, S/D regions 308, and metal material 304 of the capacitors may be filled in with a dielectric material, e.g., the dielectric material 106 described with respect to FIG. 1. Further, while FIG. 3B illustrates the nanoribbons 320 with rectangular cross-sections, as noted above, in other embodiments, the cross-sections of the nanoribbons 320 in the x-z plane, and other nanoribbons described herein, may have other cross sections, e.g., nanoribbons may be narrower or wider than illustrated in the figures.

### Example Electrical Connections to Gates and Capacitors of 1T-1C Memory Cells

As shown in FIG. 3, each capacitor within each stack may be independently controlled, and capacitors across different stacks are not coupled in the horizontal direction (as the gate lines are, as shown in FIG. 3B). The metal material 304 forming the outer metal layer of each capacitor may be coupled to a plate line, corresponding to the PL 260 of FIG. 2. The independent electrical connections to each capacitor may be formed by extending the metal material 304 in the y-direction in the coordinate system shown to different lengths at different heights along the stack 300, so that the ends of the metal material 304 resemble a staircase. Vias at different positions in the y-direction can then connect to the different capacitors or different “steps” of the staircase.

FIG. 4A is a cross-section illustrating a stack of 1T-1C memory cells formed around nanoribbons with via connections to different capacitors, according to some embodiments of the present disclosure. FIG. 4A is similar to FIG. 3A, discussed above, except that each of the capacitors 435 is a MIM capacitor (rather than a SIM capacitor), each capacitor 435 includes an extension region 410 coupled to a respective capacitor via 440, and the S/D region 308 is also coupled to a S/D via 430. The capacitor via 440 corresponds to the PL 260 in FIG. 2, while the S/D via 430 corresponds to the BL 240.

As noted above, in some cases, a MIM capacitor may be used, rather than the SIM capacitor shown in FIG. 3. In the MIM capacitor, a first layer of the metal material 304 is deposited over or around nanoribbons 420 of the channel material 104, followed by the dielectric material 302 and a second layer of the metal material 304.

Each of the memory cells in the stack 300 may be considered to be in a separate layer (e.g., a separate memory layer) of the device, and the extension region 410 extends along the memory layer, e.g., the extension region 410a is in the same layer as the nanoribbon 420a, and the extension region 410a is in a layer over the extension region 410b, which is in in the same layer as the nanoribbon 420b. Each extension region 410 is coupled to a respective capacitor via 440, and each of the capacitor vias 440 extends down from a front side of the device. The capacitor via 440a is coupled to the top memory layer, and in particular, to the extension region 410a. Each subsequent capacitor via 440b and 440c is coupled to the next extension region 410b or 410c in a lower memory layer. For example, the capacitor via 440c extends through the upper two memory layers. The capacitor vias 440 may have different lengths, i.e., heights in the z-direction. For example, the capacitor via 440a has a shorter height, also referred to as shorter length, than the capacitor via 440b.

The vias 430 and 440 may be formed from any conductive material 402, such as copper or another metal. In some embodiments, the vias 430 and/or 440 include multiple layers, e.g., one or more liner layers and a fill layer.

FIG. 4B is a cross-section illustrating multiple stacks of 1T-1C memory cells with via connections to different gate lines, according to some embodiments of the present disclosure. FIG. 4B is a cross-section through the plane GG′ in FIG. 4A. FIG. 4B illustrates three gate lines 418a, 418b, and 418c, which are similar to the gate lines 318 shown in FIG. 3B. In FIG. 4B, each gate line 418 has an extension region that is similar to the extension regions 410 of FIG. 4A, except that the gate line extension regions extend in a perpendicular direction to the extension regions 410, e.g., the capacitor extension regions 410 extend in the y-direction while the gate extension regions extend in the x-direction. Each gate line 418 (and, in particular, each extension region of the gate line) is coupled to a respective gate via 450a, 450b, or 450c, where the gate vias 450 are similar to the capacitor vias 440, described above. The gate lines 418 and/or gate vias 450 correspond to the WL 250 of FIG. 2. The gate vias 450 may have different lengths, i.e., heights in the z-direction. For example, the gate via 450a has a shorter height, also referred to as shorter length, than the gate via 450b.

### Example Stacked 1T-1C Memory Cells with Two Independent Gates

In the examples described with respect to FIGS. 3 and 4, each memory cell includes one gate that wraps around a central portion of the nanoribbon. In other embodiments, a memory cell may include two gates, e.g., a top gate and a bottom gate, that can be independently controlled. The two gates may be electrically isolated from each other, with independent vias to each gate line (e.g., one via to a top gate line that extends across a row of memory cells from a top side, and another via to a bottom gate line that extends across a row of memory cells from a bottom side).

The different gate lines may be used to apply different gate voltages to the access transistor. In some embodiments, the two gate lines may be used to provide tri-state memory, e.g., to store different levels of charge in the capacitor. As another example, the two gate lines may be used during different operating conditions, e.g., at different temperatures. As another example, the gate lines may be used at different times to enhance device longevity, e.g., using a first, lower voltage at the gate while the device is relatively new, and using a second, higher voltage at the gate when the device is older and the channel material or other components may have degraded.

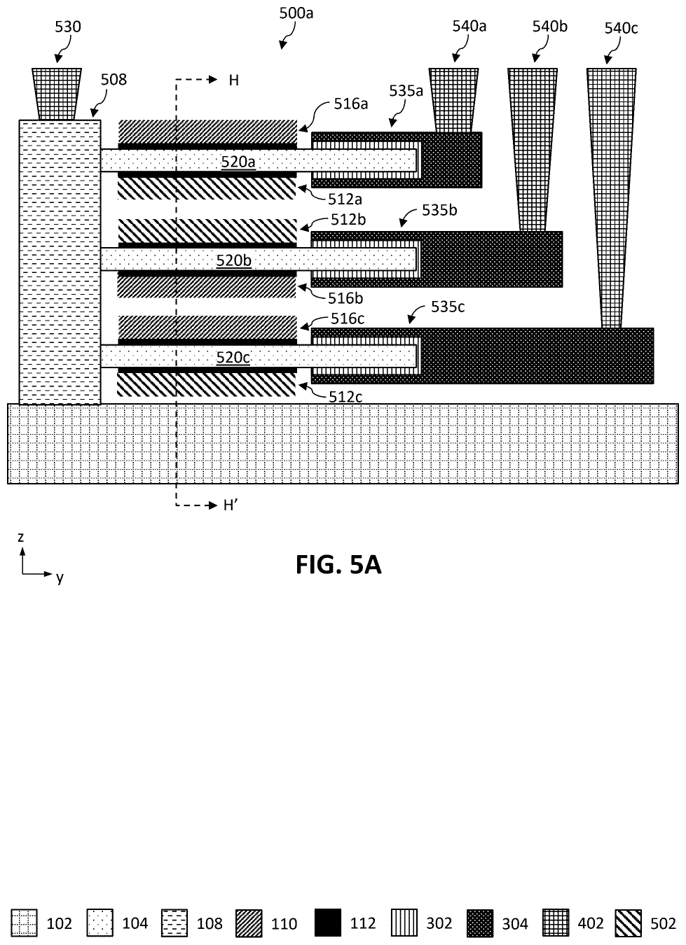

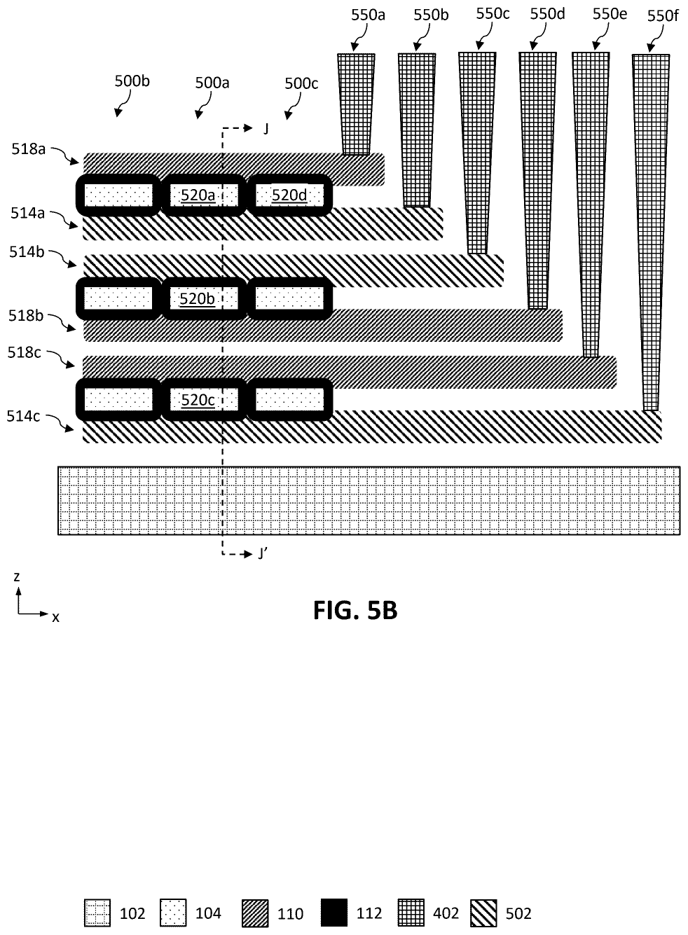

FIG. 5A is cross-section illustrating a stack 500c of 1T-1C memory cells formed around nanoribbons with independent top and bottom gates, according to some embodiments of the present disclosure. FIG. 5B is a gate cross-section through the plane HH′ in FIG. 5A, and FIG. 5A illustrates the cross-section through the plane JJ′ in FIG. 5B. A cross-section through the capacitors of FIG. 5A may be similar to the cross-section shown in FIG. 3C.

FIG. 5A includes a stack of three nanoribbons 520a, 520b, and 520c are over a support structure 102, which may be the support structure 102 described with respect to FIG. 1. The nanoribbons 520, which are formed from the channel material 104, are similar to the nanoribbons 320 and 420 described above. An S/D region 508 is at one end of the nanoribbons 520. The S/D region 508 may include the S/D materials 108 described with respect to FIG. 1. The S/D region 508 is coupled to an S/D via 530, which is similar to the S/D via 430 of FIG. 4A. The S/D region 508 may be coupled to a bit line, e.g., the S/D via 530 is an embodiment of the BL 240 of FIG. 2.

A capacitor 535 is coupled to each of the nanoribbons 520 at an end opposite the S/D region 508, e.g., the capacitor 535a is coupled to an end of the nanoribbon 520a, which is opposite the end of the nanoribbon 520a coupled to the S/D region 508. The capacitors 535, which include a layer of the dielectric material 302 over the channel material 104 and a layer of the metal material 304 over the dielectric material 302, are similar to the capacitors illustrated in FIGS. 3 and 4. While SIM capacitors are illustrated in FIG. 5A, in other embodiments, the capacitors 535 may be MIM capacitors, similar to the capacitors 435 of FIG. 4. Each of the capacitors 535 has an extension region that is coupled to a respective capacitor via 540. The arrangement of the extension regions and capacitor vias 540 are similar to the extension regions 410 and capacitor vias 440, described above. The metal material 304 of the capacitors 535 may be coupled to respective plate lines, e.g., the capacitor vias 540 are embodiments of the PLs 260 of FIG. 2.

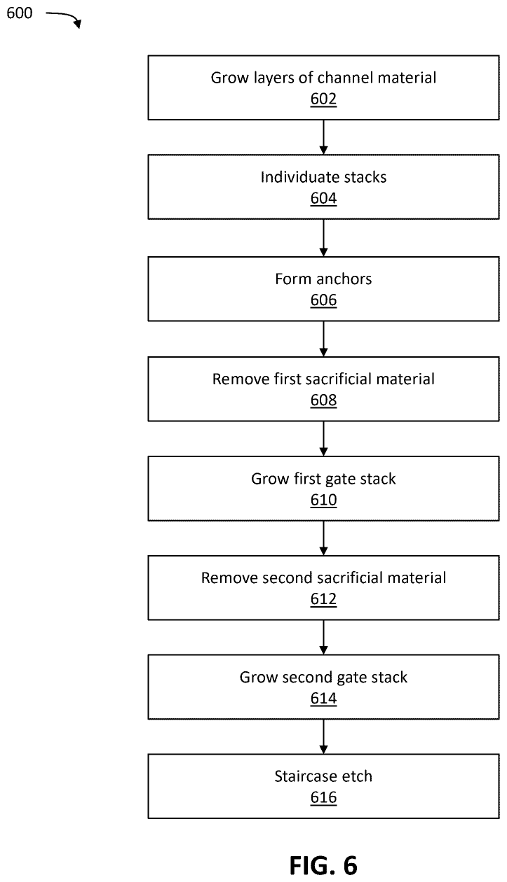

A central portion of each of the nanoribbons 320 is surrounded by the gate dielectric 112. A first gate stack 516, including the gate dielectric 112 and the gate electrode 110, is coupled to one side of each nanoribbon 520. For example, the gate stack 516a is coupled to an upper side or an upper face of the nanoribbon 520a, and the gate stack 516b is coupled to a lower side or a lower face of the nanoribbon 520b. A second gate stack 512, including the gate dielectric 112 and a gate electrode 502, is coupled to another side of each nanoribbon 520. For example, the gate stack 512a is coupled to a lower side or lower face of the nanoribbon 520a, and the gate stack 512b is coupled to an upper side or upper face of the nanoribbon 520b. In this example, the relative positions of the gate stack 512 and 516 alternate between adjacent nanoribbons 520 as a result of the processing flow illustrated in FIGS. 6-14. In other examples, the first gate stack 516 may be over each of the nanoribbons 520 and the second gate stack 512 under each of the nanoribbons 520, or vice versa. The gate electrode 502 may include any of the gate materials described with respect to the gate electrode 110. In some embodiments, the gate electrode 502 and gate electrode 110 may include different materials, e.g., different metals. For example, the gate electrode 502 may have a different work function from the gate electrode 110. In some embodiments, the gate electrode 502 may apply a different voltage level to the nanoribbons 520 from the gate electrode 110.

As in FIG. 3, the gate electrodes of different nanoribbons in the stack 500a are not physically or electrically coupled together. For example, the gate stacks 512a and 512b are physically and electrically isolated from each other. Furthermore, in some embodiments, the upper and lower gate electrodes around a given nanoribbon (e.g., the gate stacks 512a and 516a coupled to the nanoribbon 520a) are electrically isolated from each other. FIG. 5B further illustrates the electrical isolation of the upper and lower gates, as well as the gate line connections between adjacent gates in a horizontal direction, and connections to gate vias.

In the x-z cross-section illustrated in FIG. 5B, memory cells in different stacks 500b, 500a, and 500c are physically and electrically connected in the horizontal direction by gate lines 518 and 514. The gate lines 518 include the gate electrode 110, while the gate lines 514 include the gate electrode 502. For example, the gate stack 516a over the upper nanoribbon 520a is electrically and physically coupled to similar gate stacks over the upper nanoribbon in the stack 500b (to the right of the stack 500a) and over the upper nanoribbon in the stack 500c (to the left of the stack 500a). These connected gate stacks form the gate line 518a. As another example, the gate stack 512a below the upper nanoribbon 520a is electrically and physically coupled to similar gate stacks below the upper nanoribbon in the stack 500b (to the right of the stack 500a) and below the upper nanoribbon in the stack 500c (to the left of the stack 500a). These connected gate stacks form the gate line 514a. Gate lines 514b and 518b extend above and below, respectively, the middle nanoribbons in the stacks 500 (e.g., the nanoribbon 520b), and gate lines 518c and 514c extend above and below, respectively, the lower nanoribbons in the stacks 500 (e.g., the nanoribbon 520c). The gate lines 518 and 514 extend in a direction perpendicular to the length of the nanoribbons 520. In this example, the nanoribbons 520 and, more generally, the individual memory cells extend from their first end (i.e., the end of the S/D region 508) to their second end (i.e., the capacitor end) along the y-direction, while the gate lines 518 and 514 extend in the x-direction.

The spacing of the nanoribbons within each stack 500 and between adjacent stacks 500, along with the selected deposition process parameters, may enable the formation of independent gate lines along the tops and bottoms of the nanoribbons. In this example, the horizontal distance between nanoribbons in different stacks 500 is sufficiently close that the gate dielectric 112 fills the space between the stacks. For example, a space between the nanoribbon 520a and the nanoribbon 520d is filled by the gate dielectric 112, such that when the gate electrodes 110 and 502 are deposited after the gate dielectric 112, the gate dielectric 112 between the nanoribbons 520a and 520d prevents a short (i.e., a physical and electrical connection) between the gate electrodes 502 and 110 deposited under and over the nanoribbons 520a and 520d. That is, the gate dielectric 112 is between the gate electrodes 110 and 502 (of the gate lines 518a and 514a, respectively), and the gate dielectric 112 is also between the nanoribbons 520a and 520d.

The gate lines 514 and 518 have extension regions, similar to the capacitor extension regions described above, and similar to the gate extension regions shown in FIG. 4B. Each gate line 514 and 518 (and, in particular, each extension region of the gate line) is coupled to a gate via 550. For example, the gate line 518a is coupled to the gate via 550a, the gate line 514a is coupled to the gate via 550b, the gate line 514b is coupled to the gate line 550c, and so forth. The gate vias 550 may have different lengths, i.e., heights in the z-direction. For example, the gate via 550a has a shorter height, also referred to as shorter length, than the gate via 550b. The gate lines 550 correspond to the WL 250 of FIG. 2. In this example, each access transistor has two word lines that can be independently controlled, as described above.

### Example Process for Fabricating Nanoribbons with Independent Top and Bottom Gates

FIG. 6 is a flow diagram of a process 600 for fabricating a stack of nanoribbons with independent top and bottom gates, according to some embodiments of the present disclosure. The stack of nanoribbons with independent top and bottom gates may be used for access transistors, e.g., to form the access transistors for the 1T-1C memory cells illustrated in FIG. 5.

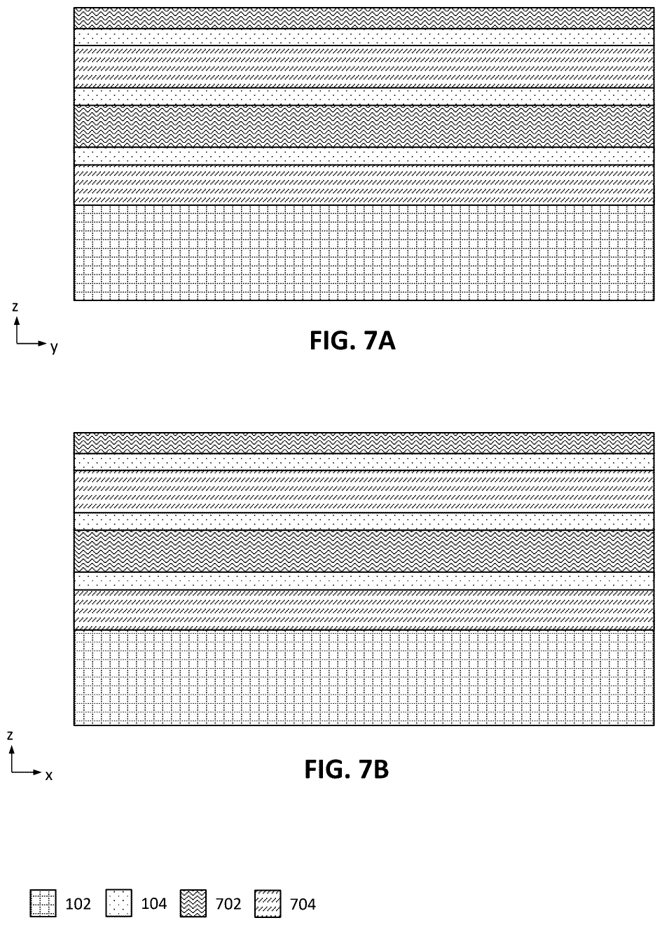

FIGS. 7-14 illustrate various steps in the processing method 600 of FIG. 6, according to some embodiments of the present disclosure. In general, the processing method 600 is performed across a wafer, with many individual stacks of transistors (or stacks of memory devices including the stacks of transistors) formed on the wafer. FIGS. 7-14 illustrate cross-sections of processing steps across several stacks of transistors. The processing method 600 describes a process of fabricating independent gates and gate lines across a stack of nanoribbons. Additional steps may be performed before, during, and/or after the process 600 to produce a device that includes the stacked transistors with independent top and bottom gates, e.g., to produce the vertically stacked memory cells shown in FIG. 5.

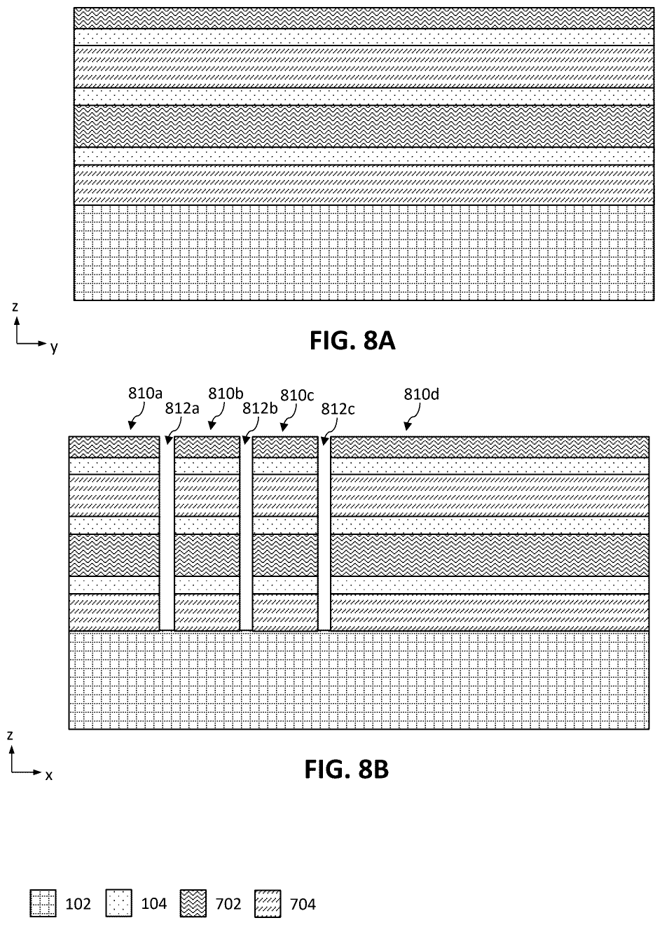

At 602, a process for growing layers of a channel material and two sacrificial materials is performed. To produce a stack of nanoribbons with independent top and bottom gates, the channel material may be grown in layers with alternating layers of two different sacrificial material between layers of channel material. FIGS. 7A and 7B are two perpendicular cross-sections illustrating layers of a channel material and two sacrificial materials, according to some embodiments of the present disclosure. FIG. 7A is a cross-section in the y-z plane, and FIG. 7B is a cross-section in the x-z plane. FIGS. 8-13 illustrate the same two cross-sections at different stages of the processing method.

FIGS. 7A and 7B illustrate three layers of the channel material 104 interspersed with layers of two different sacrificial materials 702 and 704. In this example, three layers of the channel material 104 are illustrated; in other examples, fewer or additional layers may be included. A layer of the second sacrificial material 704 is over the support structure 102, followed by a layer of the channel material 104, followed by a layer of the first sacrificial material 702, followed by another layer of the channel material 104, and then another layer of the second sacrificial material 704. This pattern may generally be followed moving upwards until a desired number of layers of the channel material 104 are formed.

The channel material 104, first sacrificial material 702, and second sacrificial material 704 include different materials. In one example, the channel material 104 is silicon, the first sacrificial material 702 includes a mixture of silicon and germanium, and the second sacrificial material 704 includes germanium. In another example, the first and second sacrificial materials 702 and 704 both include silicon and germanium, but have different relative concentrations of silicon and germanium. The sacrificial materials 702 and 704 may be chosen to have a similar crystal structure to the channel material 104, so that monocrystalline layers of the channel material 104 (or substantially monocrystalline layers, e.g., with a grain size of at least 5 nanometers, at least 20 nanometers, at least 50 nanometers, or at least 100 nanometers), monocrystalline layers of the first sacrificial material 702 (or substantially monocrystalline layers), and monocrystalline layers of the second sacrificial material 704 (or substantially monocrystalline layers) may be formed over each other. In different embodiments, the channel material 104 and/or the sacrificial materials 702 and 704 may be formed of any suitable single-crystal material, such as sapphire, quartz, silicon, a compound of silicon (e.g., silicon oxide), indium phosphide, germanium or a germanium alloy (e.g., silicon germanium), gallium, arsenic (e.g., an arsenide 11 compound, where arsenic Ill is in combination with another element such as boron, aluminum, gallium, or indium), or any group Ill-V material (i.e., materials from groups Ill and V of the periodic system of elements).

Returning to FIG. 6, at 604, a process to etch channel material to form individuated stacks of nanoribbons is performed. FIG. 8 illustrates the layers of the channel material 104 and sacrificial materials 702 and 704 after stacks have been etched to form individuated channels for different transistors or memory devices. As shown in FIG. 8B, portions of the alternating layers are removed, leaving the stacks and 810a, 810b, 810c, and 810d. The etching may be performed using a lithographic process, e.g., a mask may have been formed over the stacks 810a-810d so that the material under the masked regions is not removed. The stacks 810 are separated by etched regions 812a, 812b, and 812c, e.g., the etched region 812a is between the stacks 810a and 810b. The stacks 810 are fairly close together, i.e., the etched regions 812 relatively narrow in the x-direction, so that the gate dielectric 112 can close the gaps between the nanoribbons, as shown in FIG. 5 and illustrated further below. The stack 810d is wider in the x-direction than the other stacks; while the stacks 810a-810c may be used to form transistors or memory devices, the stack 810b may be used to form gate extension regions, as described further below. FIG. 8A illustrates a cross-section through one of the stacks, e.g., the stack 810b.

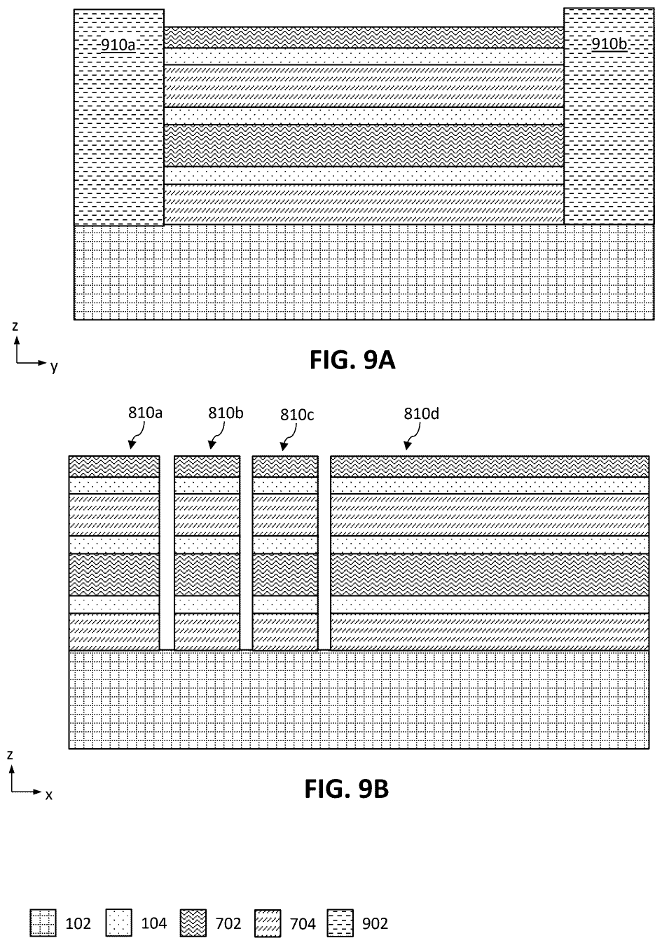

Returning to FIG. 6, at 606, a process to form anchors at opposite ends of the nanoribbons is performed. FIGS. 9A and 9B illustrate formation of anchors 910a and 910b around the stacks of the layered channel material and sacrificial materials. For example, at each end of the stacks 810 in the y-direction, a portion of the stack may be replaced with an anchor that provides physical support to the channel material 104 during later processing, e.g., when the first sacrificial material 702 and second sacrificial material 704 are removed. In some embodiments, the anchor material 902 is an S/D material, e.g., the material of the S/D regions 108, described above. In other embodiments, a temporary anchor material is used, and replaced at a later processing stage with the S/D region 108.

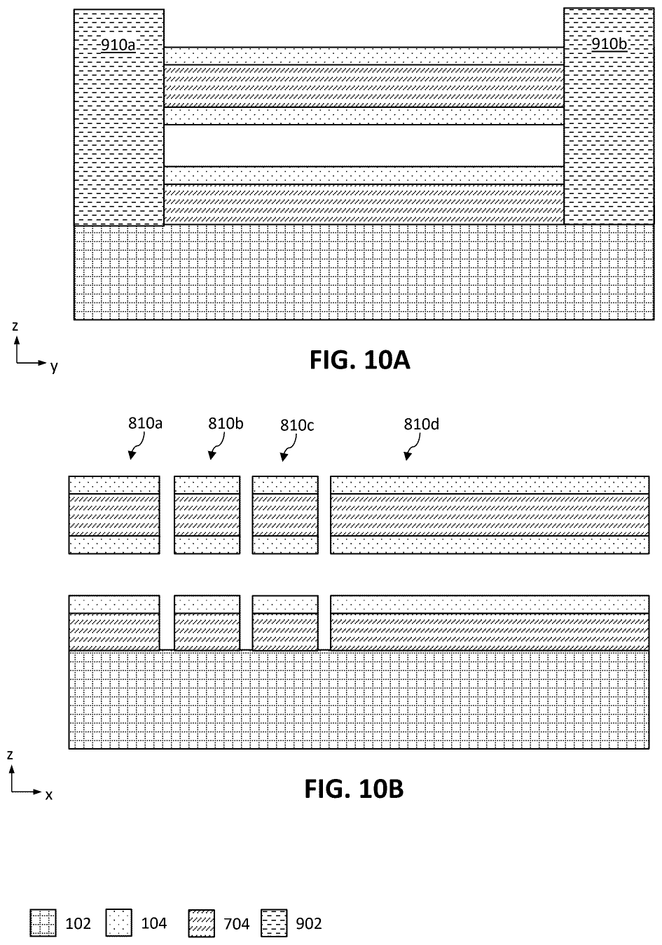

At 608, the first sacrificial material is removed from the stacks. FIGS. 10A and 10B illustrate removal of the first sacrificial material 702 from the stacks 810. In FIG. 10, the first sacrificial material 702 has been etched, leaving the upper nanoribbons and upper portion of the second sacrificial material 704 floating between the anchors 910, as illustrated in FIG. 10A. The first sacrificial material 702 may be removed using an etching process, such as dry etch, wet etch, or a combination. An etchant material used to remove the first sacrificial material 702 is selective to the first sacrificial material 702, i.e., the etchant removes the first sacrificial material 702 but does not remove the channel material 104 or the second sacrificial material 704.

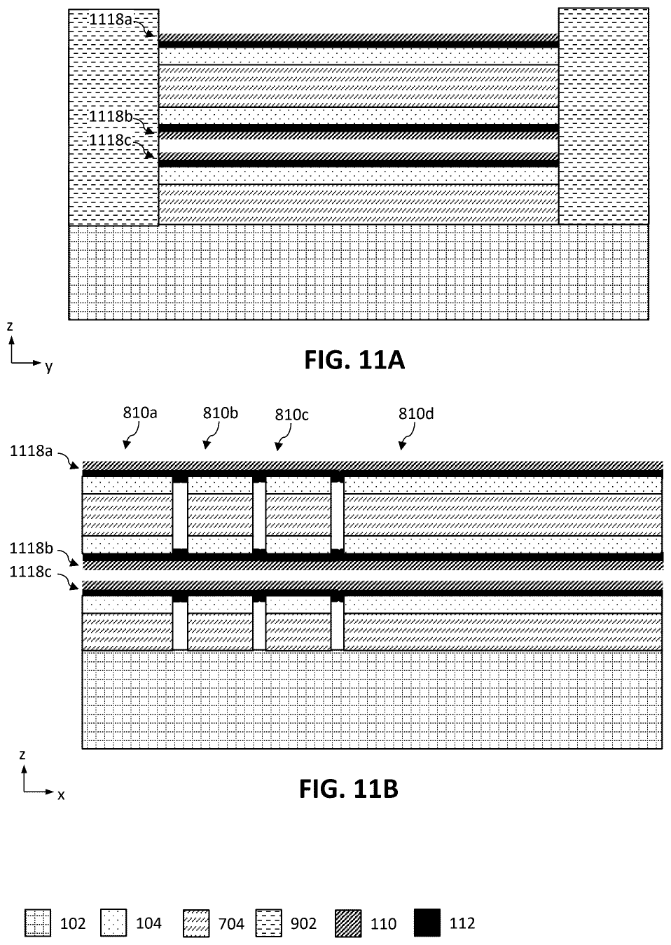

At 610, a first gate stack is grown on the channel material. FIGS. 11A and 11B illustrate a first gate stack deposited on the channels, on the sides of the channel material 104 from which the first sacrificial material 702 had been removed. For example, the gate stack forming the gate line 1118a is over an upper nanoribbon, the gate stack forming the gate line 1118b is below a middle nanoribbon, and the gate stack forming the gate line 1118c is over a lower nanoribbon. The gate stack includes the gate dielectric 112 and the gate electrode 110, referred to as a first gate electrode 110. As shown in FIG. 11B, the gate dielectric 112 fills in openings between adjacent nanoribbons in adjacent stacks 810, so that the first gate electrode 110 does not enter areas of the etched regions 812 between adjacent nanoribbons.

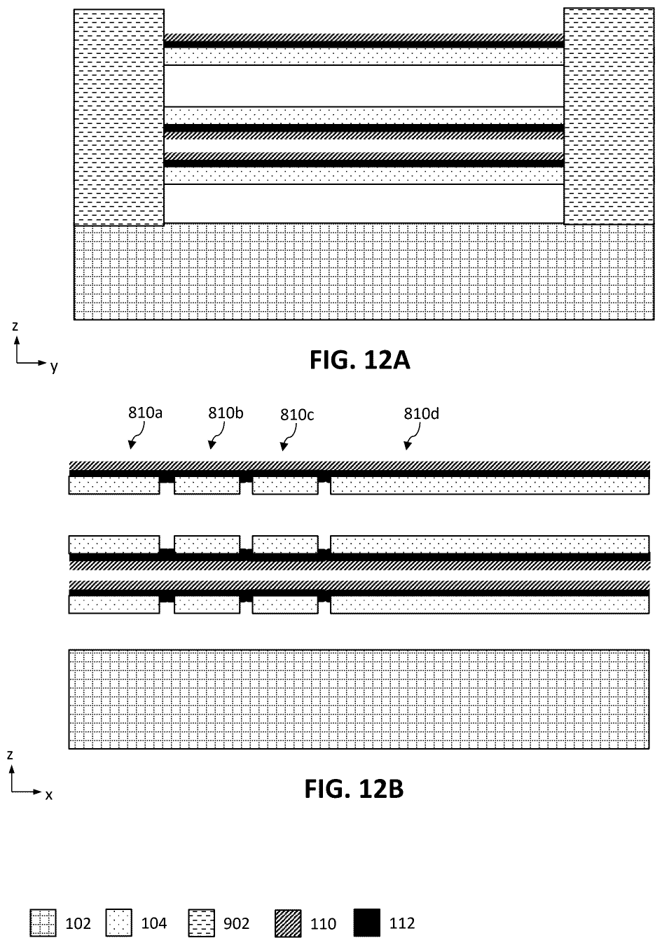

At 612, the second sacrificial material is removed from the stacks. FIGS. 12A and 12B illustrate removal of the second sacrificial material 704 from the stacks 810. In FIG. 12, the second sacrificial material 704 has been etched, leaving the nanoribbons and first gate lines 1118 floating between the anchors 910, as illustrated in FIG. 12. The second sacrificial material 704 may be removed using an etching process, such as dry etch, wet etch, or a combination. An etchant material used to remove the second sacrificial material 704 is selective to the second sacrificial material 704, i.e., the etchant removes the second sacrificial material 704 but does not remove the channel material 104.

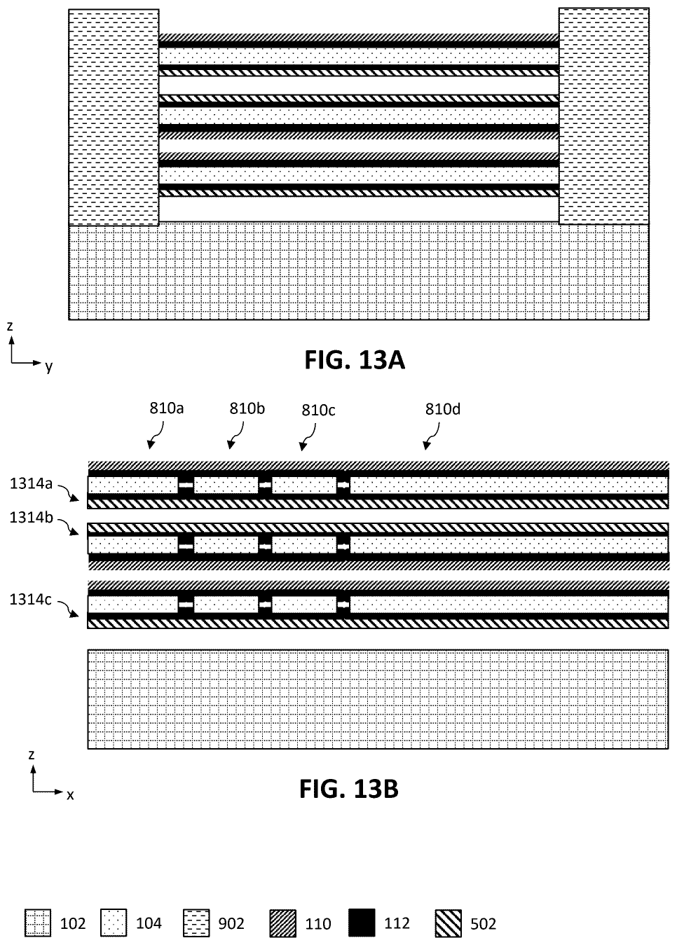

At 614, a second gate stack is grown on the channel material. FIGS. 13A and 13B illustrate a second gate stack deposited on the channels, on the sides of the channel material 104 from which the second sacrificial material 704 had been removed. For example, the gate stack forming the gate line 1314a is below an upper nanoribbon, the gate stack forming the gate line 1314b is above a middle nanoribbon, and the gate stack forming the gate line 1314c is below a lower nanoribbon. The gate stack includes the gate dielectric 112 and the gate electrode 502, referred to as a second gate electrode 502. As shown in FIG. 13B, the gate dielectric 112 fills in openings between adjacent nanoribbons in adjacent stacks 810, so that the second gate electrode 502 does not enter areas of the etched regions 812 between adjacent nanoribbons. Along a given row of nanoribbons in the x-direction, the gate lines 1118 and 1314 are isolated by the channel material 104 or the gate dielectric 112.

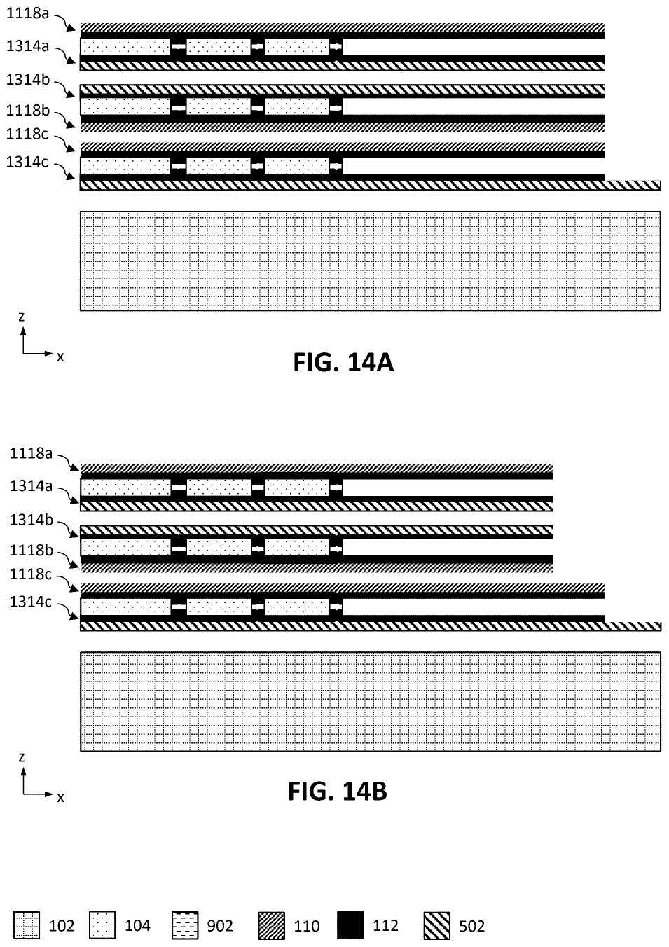

At 616, a staircase etch process is performed to enable connections to the individual gate lines, e.g., the gate vias 550 shown in FIG. 5. FIGS. 14A and 14B illustrate two steps in forming a staircase structure for the gate vias, according to some embodiments of the present disclosure. FIGS. 14A and 14B both illustrate cross-sections in the x-z plane, e.g., the view shown in FIG. 13B. A multi-step lithographic process may be used to form the gate extension regions. The nanoribbons, e.g., the stacks 810a, 810b, and 810c, may generally be masked during this process. The channel material 104 in the extension region (i.e., in the stack 810d) may be removed, as shown in FIG. 14A. In some embodiments, the gate dielectric 112 in this region is also removed. In addition, the right-most portions of the gate lines 1118a, 1314a, 1314b, 1118b, and 1118c in the region of the stack 810d are removed, as shown in FIG. 14A. This leaves the right-most portion of the gate line 1314c exposed, so that a via (e.g., the via 550f of FIG. 5B) can be formed over the gate line 1314c.

After exposing the gate line 1314c, the right-most remaining portions of the gate lines 1118a, 1314a, 1314b, and 1118b in the region of the stack 810d are removed, as shown in FIG. 14B. This leaves the right-most remaining portion of the gate line 1118c exposed, so that a via (e.g., the via 550e of FIG. 5B) can be formed over the gate line 1118c. This process may be continued until staircase extension region are formed across the gate lines 1118a, 1314a, 1314b, 1118b, 1118c, and 1314c.

### Example Memory Cells Formed Across Multiple Nanoribbons

While in the examples of FIGS. 3-14, a memory cell was formed around a single nanoribbon, in other embodiments, a memory cell may be formed around multiple nanoribbons. For example, a set of two memory cells may be formed around a stack of four memory cells, with one memory cell formed around the top two nanoribbons, and another memory cell formed around the lower two nanoribbons. As another example, a set of two memory cells may be formed around a stack of six memory cells, with one memory cell formed around the top three nanoribbons, and another memory cell formed around the lower three nanoribbons. As yet another example, a set of three memory cells may be formed around a stack of six memory cells, with one memory cell formed around the top two nanoribbons, a second memory cell formed around the middle two nanoribbons, and a third memory cell formed around the lowest two nanoribbons. Additional stacks with a greater number of nanoribbons and/or memory cells are possible.

FIG. 15 is a cross-section of an alternate embodiment of two stacked 1T-1C memory cells formed around four nanoribbons, in accordance with any of the embodiments disclosed herein. FIG. 15 includes a stack of four nanoribbons 1520a-1520d, which may be similar to the nanoribbons 320 described above. The spacing between the nanoribbons 1520b and 1520c may be greater than the spacing between the upper two nanoribbons 1520a and 1520b or lower two nanoribbons 1520c and 1520d. This spacing enables a first gate stack 1516a to be deposited around the upper two nanoribbons 1520a and 1520b and a second, independent gate stack 1516b to be deposited around the lower two nanoribbons 1520c and 1520d. Likewise, a first capacitor 1535a is deposited around the ends of the upper two nanoribbons 1520a and 1520b, and a second, independent capacitor 1535b is deposited around the ends of the lower two nanoribbons 1520c and 1520d. The gate stacks and capacitors may be similar to any of the gate stacks and capacitors described above. The gate or wordline connections, capacitor or plate line connections, and bit line or source/drain connections may be similar to those illustrated with respect to FIGS. 4A and 4B.

### Example Devices

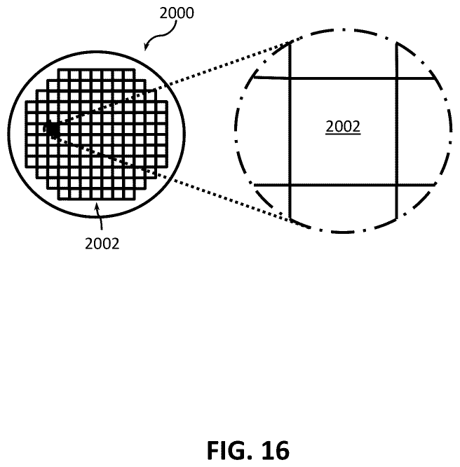

The circuit devices with stacks of 1T-1C memory cells formed around nanoribbons disclosed herein may be included in any suitable electronic device. FIGS. 16-20 illustrate various examples of apparatuses that may include the one or more transistors or memory cells disclosed herein, which may have been fabricated using the processes disclosed herein.

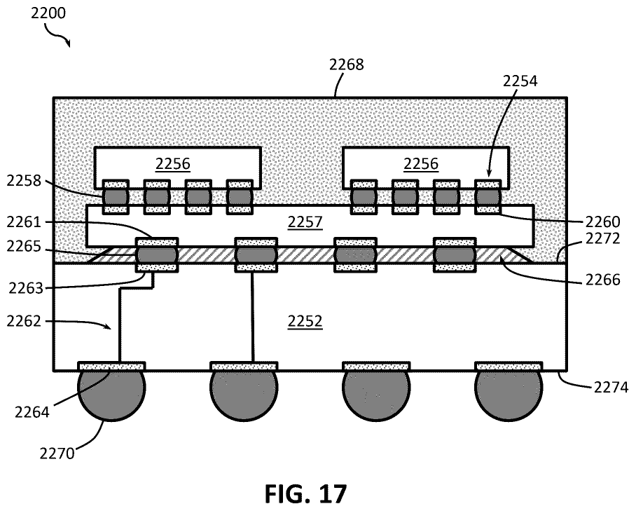

FIG. 16 illustrates top views of a wafer 2000 and dies 2002 that may include one or more stacks of 1T-1C memory cells formed around nanoribbons in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 17. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more stacks of 1T-1C memory cells formed around nanoribbons as described herein). After the fabrication of the semiconductor product is complete (e.g., after manufacture of any embodiment of the memory devices as described herein), the wafer 2000 may undergo a singulation process in which each of the dies 2002 is separated from one another to provide discrete “chips” of the semiconductor product. In particular, devices that include one or more stacks of 1T-1C memory cells formed around nanoribbons as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a hysteretic memory device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 17) or other logic that is configured to store information in the memory devices or execute instructions stored in the memory array.

FIG. 17 is a side, cross-sectional view of an example IC package 2200 that may include one or more stacks of 1T-1C memory cells formed around nanoribbons in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 17 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 17 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

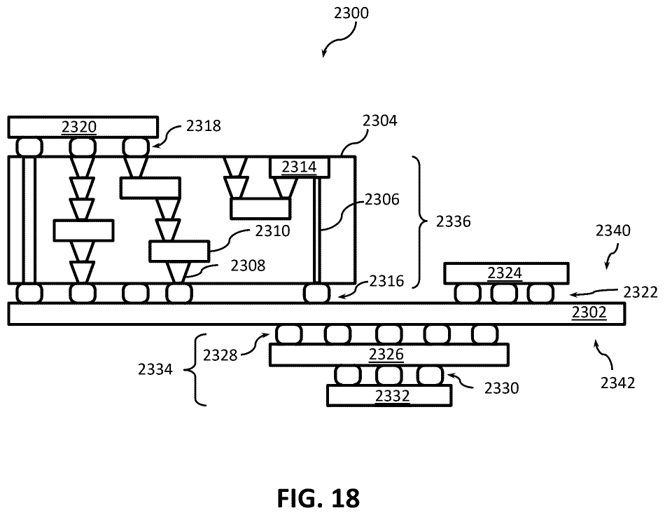

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 17 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 18.

The dies 2256 may take the form of any of the embodiments of the die 2002 discussed herein (e.g., may include any of the embodiments of the IC devices with one or more stacks of 1T-1C memory cells formed around nanoribbons as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more IC devices with one or more stacks of 1T-1C memory cells formed around nanoribbons, e.g., as discussed above; in some embodiments, at least some of the dies 2256 may not include any stacks of 1T-1C memory cells formed around nanoribbons.

The IC package 2200 illustrated in FIG. 17 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 17, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 18 is a cross-sectional side view of an IC device assembly 2300 that may include components having one or more stacks of 1T-1C memory cells formed around nanoribbons in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more stacks of 1T-1C memory cells formed around nanoribbons in accordance with any of the embodiments disclosed herein; e.g., any of the IC packages discussed below with reference to the IC device assembly 2300 may take the form of any of the embodiments of the IC package 2200 discussed above with reference to FIG. 17 (e.g., may include one or more stacks of 1T-1C memory cells formed around nanoribbons provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 18 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 18), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 16), an IC device, or any other suitable component. In particular, the IC package 2320 may include one or more stacks of 1T-1C memory cells formed around nanoribbons as described herein. Although a single IC package 2320 is shown in FIG. 18, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 18, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group Ill-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 18 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

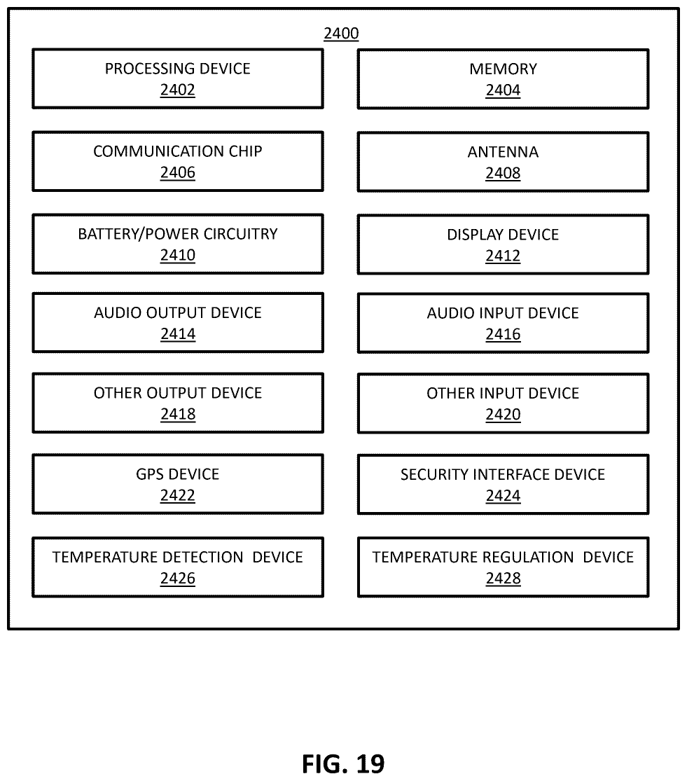

FIG. 19 is a block diagram of an example computing device 2400 that may include one or more components including one or more IC devices with one or more stacks of 1T-1C memory cells formed around nanoribbons in accordance with any of the embodiments disclosed herein. For example, any suitable ones of the components of the computing device 2400 may include a die (e.g., the die 2002 of FIG. 16) having one or more stacks of 1T-1C memory cells formed around nanoribbons as described herein. Any one or more of the components of the computing device 2400 may include, or be included in, an IC package 2200 of FIG. 17 or an IC device 2300 of FIG. 18.

A number of components are illustrated in FIG. 19 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 19, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

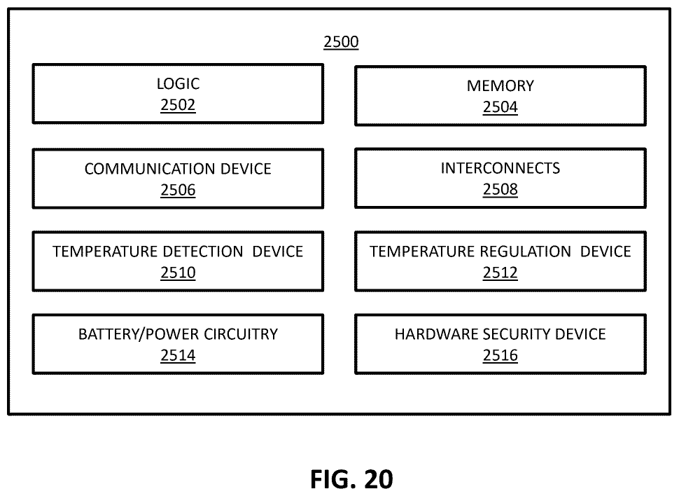

FIG. 20 is a block diagram of an example processing device 2500 that may include one or more IC devices with one or more stacks of 1T-1C memory cells formed around nanoribbons in accordance with any of the embodiments disclosed herein. For example, any suitable ones of the components of the processing device 2500 may include a die (e.g., the die 2002 of FIG. 16) having one or more stacks of 1T-1C memory cells formed around nanoribbons as described herein. Any one or more of the components of the processing device 2500 may include, or be included in, an IC device 1400 (FIG. 18). Any one or more of the components of the processing device 2500 may include, or be included in, an IC package 2200 of FIG. 17 or an IC device 2300 of FIG. 18. Any one or more of the components of the processing device 2500 may include, or be included in, a computing device 2400 of FIG. 19; for example, the processing device 2500 may be the processing device 2402 of the computing device 2400.

A number of components are illustrated in FIG. 20 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 20, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 1604 (FIG. 19). In some embodiments, the memory 2504 may be a designated device configured to provide storage functionality for the components of the processing device 2500 (i.e., local), while the memory 1604 may be configured to provide system-level storage functionality for the entire computing device 1600 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , mₙ) in which each member mᵢ is typically smaller and faster than the next highest member mᵢ₊ᵢ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 1606 (FIG. 19). In some embodiments, the communication device 2506 may be a designated device configured to provide communication functionality for the components of the processing device 2500 (i.e., local), while the communication chip 1606 may be configured to provide system-level communication functionality for the entire computing device 1600 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 19 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 19 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 19. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 19. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

### Select Examples

The following paragraphs provide various examples of the embodiments disclosed herein.

Example 1 provides a device including a plurality of semiconductor regions arranged in a stack, each of the plurality of semiconductor regions having a first end and a second end; a source or drain region coupled to the plurality of semiconductor regions at the first end of the respective semiconductor regions; and a plurality of capacitors, each of the plurality of capacitors coupled to one of the plurality of semiconductor regions at the second end of the respective semiconductor regions.

Example 2 provides the device of example 1, where a first via is coupled to a first capacitor of the plurality of capacitors, and a second via is coupled to a second capacitor of the plurality of capacitors.

Example 3 provides the device of example 2, where the first capacitor is in a first memory layer, and the second via extends through the first memory layer to the second capacitor.

Example 4 provides the device of any preceding example, further including a plurality of conductive regions, each of the plurality of conductive regions coupled to a respective one of the plurality of semiconductor regions at a portion of the semiconductor region between the first end and the second end.

Example 5 provides the device of example 4, where a first direction is a direction from the first end to the second end of one of the semiconductor regions, and the conductive regions extend in a second direction perpendicular to the first direction.

Example 6 provides the device of example 5, where a first gate via is coupled to a conductive region of the plurality of conductive regions, a second gate via is coupled to a second conductive region of the plurality of conductive regions, and the second gate via is longer than the first gate via.

Example 7 provides the device of any of examples 4-6, further including a second plurality of semiconductor regions arranged in a second stack, where one of the plurality of conductive regions is further coupled to one of the second plurality of semiconductor regions in the second stack.

Example 8 provides the device of example 7, where the plurality of capacitors is a first plurality of capacitors, the device further including a second plurality of capacitors, each of the second plurality of capacitors coupled to one of the second plurality of semiconductor regions, where the second plurality of capacitors are electrically isolated from the first plurality of capacitors.

Example 9 provides the device of any preceding example, where the stack is a first stack, the device further including a second plurality of semiconductor regions arranged in a second stack, where a first distance between a first pair of adjacent semiconductor regions within the second stack is less than a second distance between a second pair of adjacent semiconductor regions, one of the second pair in the first stack and one of the second pair in the second stack.

Example 10 provides the device of any preceding example, where one of the plurality of capacitors includes a dielectric material over the second end of the semiconductor region; and a conductive material over the dielectric material.

Example 11 provides the device of example 10, where the conductive material is in a first conductive layer, and the one of the plurality of capacitors further includes a second conductive layer between the dielectric material and the second end of the semiconductor region.

Example 12 provides an integrated circuit (IC) device including a channel region having a first end, a second end, a top, and a bottom, first end opposite the second end, and the bottom opposite the top; a bit line coupled to the first end of the channel region; a capacitor coupled to the second end of the channel region; a first gate coupled to the top of the channel region, the first gate between the bit line and the capacitor; and a second gate coupled to the bottom of the channel region, the second gate between the bit line and the capacitor.

Example 13 provides the IC device of example 12, where the first gate includes a first gate material, and the second gate includes a second gate material different from the first gate material.

Example 14 provides the IC device of example 13, where the first gate material has a first work function, and the second gate material has a second work function different from the first work function.

Example 15 provides the IC device of example 13, where the channel region is a first channel region, the IC device further including a second channel region; a first gate line extending across the top of the first channel region and a top of the second channel region, the first gate line including the first gate; and a second gate line extending across the bottom of the first channel region and a bottom of the second channel region, the second gate line including the second gate.

Example 16 provides the IC device of example 15, further including a first via coupled to the first gate line; and a second via coupled to the second gate line.

Example 17 provides the IC device of example 15 or 16, further including a dielectric material between the first channel region and the second channel region, the dielectric material further between the first gate line and the second gate line.

Example 18 provides the IC device of example 17, where the dielectric material is a gate oxide.

Example 19 provides the IC device of any of examples 12-18, where the capacitor includes a dielectric material over the second end of the channel region; and a conductive material over the dielectric material.

Example 20 provides the IC device of example 19, where the conductive material is in a first conductive layer, and the one of the plurality of capacitors further includes a second conductive layer between the dielectric material and the second end of the channel region.

Example 21 provides the IC device of any of examples 12-20, where the channel region is a first channel region, the IC device further including a second channel region stacked over the first channel region; a second capacitor coupled to an end of the second channel region; a third gate coupled to a top of the second channel region; and a fourth gate coupled to a bottom of the second channel region.

Example 22 provides a method including forming a stack of materials, the stack including a semiconductor, a first sacrificial material, and a second sacrificial material; removing at least a portion of the first sacrificial material to expose a first region of the semiconductor; depositing a first conductive material over the exposed first region of the semiconductor; removing at least a portion of the second sacrificial material to expose a second region of the semiconductor; depositing a second conductive material over the exposed second region of the semiconductor.

Example 23 provides the method of example 22, where the first conductive material is different from the second conductive material.

Example 24 provides the method of example 22 or 23, further including forming a capacitor coupled to the semiconductor.

Example 25 provides the method of any of examples 22-24, where the semiconductor has a ribbon shape, the first conductive material is over a top of the ribbon, and the second conductive material is under a bottom of the ribbon.

Example 26 provides the method of any of examples 22-25, where the first conductive material is electrically isolated from the second conductive material.

Example 27 provides the method of any of examples 22-26, where the semiconductor material includes silicon, and the first sacrificial material and the second sacrificial material include germanium.

Example 28 provides the method of example 27, where the first sacrificial material and the second sacrificial material include different amounts of germanium.

Example 29 provides an IC package that includes an IC die, including one or more of the IC devices according to any one of the preceding examples. The IC package may also include a further component, coupled to the IC die.

Example 30 provides the IC package according to example 29, where the further component is one of a package substrate, a flexible substrate, or an interposer.

Example 31 provides the IC package according to examples 29 or 30, where the further component is coupled to the IC die via one or more first level interconnects.

Example 32 provides the IC package according to example 31, where the one or more first level interconnects include one or more solder bumps, solder posts, or bond wires.

Example 33 provides a computing device that includes a circuit board; and an IC die coupled to the circuit board, where the IC die includes one or more of the transistor/IC devices according to any one of the preceding examples (e.g., transistor/IC devices according to any one of examples 1-21), and/or the IC die is included in the IC package according to any one of the preceding examples (e.g., the IC package according to any one of examples 29-32).

Example 34 provides the computing device according to example 33, where the computing device is a wearable computing device (e.g., a smart watch) or hand-held computing device (e.g., a mobile phone).

Example 35 provides the computing device according to examples 33 or 34, where the computing device is a server processor.

Example 36 provides the computing device according to examples 33 or 34, where the computing device is a motherboard.

Example 37 provides the computing device according to any one of examples 33-36, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A device comprising:
a plurality of semiconductor regions arranged in a stack, each of the plurality of semiconductor regions having a first end and a second end;
a source or drain region coupled to the plurality of semiconductor regions at the first end of the respective semiconductor regions; and
a plurality of capacitors, each of the plurality of capacitors coupled to one of the plurality of semiconductor regions at the second end of the respective semiconductor regions.

2. The device of claim 1, wherein a first via is coupled to a first capacitor of the plurality of capacitors, and a second via is coupled to a second capacitor of the plurality of capacitors.

3. The device of claim 2, wherein the first capacitor is in a first memory layer, and the second via extends through the first memory layer to the second capacitor.

4. The device claim 1, further comprising a plurality of conductive regions, each of the plurality of conductive regions coupled to a respective one of the plurality of semiconductor regions at a portion of the semiconductor region between the first end and the second end.

5. The device of claim 4, wherein a first direction is a direction from the first end to the second end of one of the semiconductor regions, and the conductive regions extend in a second direction perpendicular to the first direction.

6. The device of claim 5, wherein a first gate via is coupled to a conductive region of the plurality of conductive regions, a second gate via is coupled to a second conductive region of the plurality of conductive regions, and the second gate via is longer than the first gate via.

7. The device of claim 4, further comprising a second plurality of semiconductor regions arranged in a second stack, wherein one of the plurality of conductive regions is further coupled to one of the second plurality of semiconductor regions in the second stack.

8. The device of claim 7, wherein the plurality of capacitors is a first plurality of capacitors, the device further comprising a second plurality of capacitors, each of the second plurality of capacitors coupled to one of the second plurality of semiconductor regions, wherein the second plurality of capacitors are electrically isolated from the first plurality of capacitors.

9. The device of claim 1, wherein the stack is a first stack, the device further comprising a second plurality of semiconductor regions arranged in a second stack, wherein a first distance between a first pair of adjacent semiconductor regions within the second stack is less than a second distance between a second pair of adjacent semiconductor regions, one of the second pair in the first stack and one of the second pair in the second stack.

10. The device of claim 1, wherein one of the plurality of capacitors comprises:
a dielectric material over the second end of the semiconductor region; and
a conductive material over the dielectric material.

11. The device of claim 10, wherein the conductive material is in a first conductive layer, and the one of the plurality of capacitors further comprises a second conductive layer between the dielectric material and the second end of the semiconductor region.

12. The device of claim 1, wherein the device is a first component of an electronics package, the electronics package further comprising a second component coupled to the first component.

13. An integrated circuit (IC) device comprising:
a channel region having a first end, a second end, a top, and a bottom, first end opposite the second end, and the bottom opposite the top;
a bit line coupled to the first end of the channel region;
a capacitor coupled to the second end of the channel region;
a first gate coupled to the top of the channel region, the first gate between the bit line and the capacitor; and
a second gate coupled to the bottom of the channel region, the second gate between the bit line and the capacitor.

14. The IC device of claim 13, wherein the first gate comprises a first gate material, and the second gate comprises a second gate material different from the first gate material.

15. The IC device of claim 14, wherein the first gate material has a first work function, and the second gate material has a second work function different from the first work function.

16. The IC device of claim 13, wherein the channel region is a first channel region, the IC device further comprising:
a second channel region;
a first gate line extending across the top of the first channel region and a top of the second channel region, the first gate line including the first gate; and
a second gate line extending across the bottom of the first channel region and a bottom of the second channel region, the second gate line including the second gate.

17. The IC device of claim 16, further comprising:
a dielectric material between the first channel region and the second channel region, the dielectric material further between the first gate line and the second gate line.

18. The IC device of claim 13, wherein the channel region is a first channel region, the IC device further comprising:
a second channel region stacked over the first channel region;
a second capacitor coupled to an end of the second channel region;
a third gate coupled to a top of the second channel region; and
a fourth gate coupled to a bottom of the second channel region.

19. A method comprising:
forming a stack of materials, the stack comprising a semiconductor, a first sacrificial material, and a second sacrificial material;
removing at least a portion of the first sacrificial material to expose a first region of the semiconductor;
depositing a first conductive material over the exposed first region of the semiconductor;
removing at least a portion of the second sacrificial material to expose a second region of the semiconductor; and
depositing a second conductive material over the exposed second region of the semiconductor.

20. The method of claim 19, further comprising forming a capacitor coupled to the semiconductor.
